(19) United States
(12) Patent Application Publication
(10) Pub. No.: US 2026/0188249 A1
(43) Pub. Date: Jul. 2, 2026

(54) DRIVING CIRCUIT AND ELECTRONIC DEVICE

(71) Applicant: SAMSUNG DISPLAY CO., LTD., Yongin-si (KR)

(72) Inventors: Minjae Jeong, Yongin-si (KR); Ilnam Kim, Yongin-si (KR); Minkyu Woo, Yongin-si (KR); Jaeyong Jang, Yongin-si (KR); Jaehyung Cho, Yongin-si (KR)

(21) Appl. No.: 19/366,809

(22) Filed: Oct. 23, 2025

(30) Foreign Application Priority Data
Dec. 31, 2024 (KR) 10-2024-0202728

(51) Int. Cl. G09G 3/3266

(52) U.S. Cl. CPC G09G 3/3266; G09G 2310/0286; G09G 2310/08; G09G 2330/021; G09G 2340/0435

(57) ABSTRACT

Each of a plurality of stages of a driving circuit includes an input circuit configured to transmit a start signal to a first node, a first output circuit connected to a first terminal to which a first voltage is input and a second terminal to which a second voltage is input, the first output circuit being configured to output an output signal to a signal line, a second output circuit connected to the first terminal and a third terminal to which a third voltage is input, the second output circuit being configured to output a carry signal to a next stage, and a control circuit configured to control voltages of nodes to which the first output circuit and the second output circuit are connected according to a voltage of the first node.

### CROSS-REFERENCE TO RELATED APPLICATION

This U.S. patent application claims priority under 35 U.S.C. § 119 to Korean Patent Application No. 10-2024-0202728, filed on Dec. 31, 2024, in the Korean Intellectual Property Office, the disclosure of which is incorporated by reference in its entirety herein.

### 1. TECHNICAL FIELD

The present disclosure is directed to a driving circuit, and more particularly, to a driving circuit capable of outputting a gate signal, and a display device and an electronic device including the driving circuit.

### 2. DISCUSSION OF RELATED ART

A display devices typically includes a pixel area including a plurality of pixels, a gate driving circuit, a data driving circuit, and a controller. The gate driving circuit may include stages respectively connected to gate lines, each stage being configured to supply a gate signal to its corresponding gate line in response to control signals from the controller. However, the gate driving circuit may have difficulty in maintaining stable gate signal output under low-voltage conditions. Accordingly, this may result in increased power consumption and reduced signal reliability.

### SUMMARY

One or more embodiments include a driving circuit capable of outputting a gate

signal with low power and stably, and a display device and an electronic device including the driving circuit. However, the technical objectives achievable by the disclosure are not limited thereto, as other technical objectives may be achieved.

According to an embodiment, a driving circuit includes a plurality of stages. Each of the plurality of stages includes an input circuit, a first output circuit, a second output circuit, and a control circuit. The input circuit is configured to transmit a start signal to a first node. The first output circuit is connected to a first terminal receiving a first voltage and a second terminal receiving a second voltage. The first output circuit is configured to output an output signal to a signal line. The second output circuit is connected to the first terminal and a third terminal receiving a third voltage. The second output circuit is configured to output a carry signal to a next stage. The control circuit is configured to control voltages of nodes to which the first output circuit and the second output circuit are connected according to a voltage of the first node. A high-level voltage of the output signal is the first voltage, and a low-level voltage of the output signal is the second voltage that is lower than the first voltage. A high-level voltage of the carry signal is the first voltage, and a low-level voltage of the carry signal is the third voltage that is lower than the second voltage.

In an embodiment, the input circuit may include a first transistor connected to the first node and to an input terminal that receives the start signal, and including a gate connected to a clock terminal receiving a clock signal.

In an embodiment, the control circuit may include a second transistor connected to the first node and a second node, and including a gate connected to the third terminal, a third transistor connected to the first terminal and a third node, and including a gate connected to the first node, and a fourth transistor connected to the third node and the third terminal, and including a gate connected to the second node.

In an embodiment, channel types of the third transistor and the fourth transistor may be different from each other.

In an embodiment, the first output circuit may include a fifth transistor connected to the first terminal and a first output terminal, and including a gate connected to the third node, and a sixth transistor connected to the first output terminal and the second terminal, and including a gate connected to the second node.

In an embodiment, the first output circuit may further include a first capacitor connected to the first output terminal and the second node, and a second capacitor connected to the first terminal and the third node.

In an embodiment, the second output circuit may include a seventh transistor connected to the first terminal and a second output terminal, and including a gate connected to the third node, and an eighth transistor connected to the second output terminal and the third terminal, and including a gate connected to the third node.

In an embodiment, channel types of the seventh transistor and the eighth transistor may be different from each other.

In an embodiment, when a low-level voltage of the start signal is transmitted to the second node to change the output signal from the first voltage to the second voltage, a voltage of the second node may decrease by a difference between the first voltage and the second voltage, and the voltage of the second node may be lower than a voltage of the first node.

In an embodiment, the driving circuit may further include a selection circuit connected between the control circuit and the first output circuit, wherein the selection circuit includes a first selection transistor connected to the second node and a fourth node, and including a gate connected to a control terminal receiving a selection control signal, and a second selection transistor connected to the third node and a fifth node, and including a gate connected to the control terminal.

In an embodiment, the control circuit may include a second transistor connected to the first node and a second node, and including a gate connected to the third terminal, a third transistor connected to the first terminal and a third node, and including a gate connected to the first node, and a fourth transistor connected to the third node and the third terminal, and including a gate connected to the second node.

In an embodiment, channel types of the third transistor and the fourth transistor may be different from each other.

In an embodiment, the first output circuit may include a fifth transistor connected to the first terminal and a first output terminal, and including a gate connected to the fifth node, and a sixth transistor connected to the first output terminal and the second terminal, and including a gate connected to the fourth node.

In an embodiment, the first output circuit may further include a first capacitor connected to the first output terminal and the fourth node, and a second capacitor connected to the first terminal and the fifth node.

In an embodiment, the second output circuit may include a seventh transistor connected to the first terminal and a second output terminal, and including a gate connected to the third node, and an eighth transistor connected to the second output terminal and the third terminal, and including a gate connected to the second node.

In an embodiment, the driving circuit may further include a third capacitor connected to the second output terminal and the second node.

In an embodiment, when a low-level voltage of the start signal is transmitted to the second node to change the carry signal from the first voltage to the third voltage, a voltage of the second node may decrease by a difference between the first voltage and the third voltage, and the voltage of the second node may be lower than a voltage of the first node.

According to an embodiment, an electronic device includes a controller and a driving circuit. The controller is configured to receive a multi-frequency driving flag signal from a processor and output a multi-frequency driving control signal based on the multi-frequency driving flag signal. The driving circuit includes a plurality of stages configured to receive the multi-frequency driving control signal and output a gate signal at a different frequency for each area of a display area. Each of the plurality of stages includes an input circuit configured to transmit a start signal to a first node, a first output circuit connected to a first terminal receiving a first voltage and a second terminal receiving a second voltage, the first output circuit being configured to output an output signal to a signal line, a second output circuit connected to the first terminal and a third terminal receiving a third voltage, the second output circuit being configured to output a carry signal to a next stage, a control circuit configured to control voltages of nodes to which the first output circuit and the second output circuit are connected according to a voltage of the first node, and a selection circuit connected between the control circuit and the first output circuit, and configured to control output of the output signal of the first output circuit. The second output circuit includes a second pull-up transistor connected to the first terminal and a second output terminal, and including a gate connected to a third node, a second pull-down transistor connected to the second output terminal and the third terminal, and including a gate connected to a second node, and a capacitor connected to the second output terminal and the second node.

In an embodiment, the selection circuit may include a first selection transistor connected to the second node and a fourth node, and including a gate connected to a control terminal receiving a selection control signal, and a second selection transistor connected to the third node and a fifth node, and including a gate connected to the control terminal.

In an embodiment, the first output circuit may include a first pull-up transistor connected to the first terminal and a first output terminal, and including a gate connected to the fifth node, a first pull-down transistor connected to the first output terminal and the second terminal, and including a gate connected to the fourth node, a first capacitor connected to the first output terminal and the fourth node, and a second capacitor connected to the first terminal and the fifth node.

According to an embodiment, a display device is provided that includes a display panel including a display area divided into a plurality of regions; a controller configured to generate a driving control signal based on a received control input; and a gate driving circuit having a plurality of stages, each of the plurality of stages configured to receive the driving control signal and to output a gate signal to a corresponding region of the display area. Each of the plurality of stages includes: an input circuit configured to transmit a start signal to a first node; a first output circuit connected to a first voltage terminal and a second voltage terminal, and configured to output an output signal to a signal line; a second output circuit connected to the first voltage terminal and a third voltage terminal, and configured to output a carry signal to a subsequent stage; a control circuit configured to control voltages of one or more nodes associated with the first output circuit and the second output circuit based on a voltage of the first node; and a selection circuit configured to control whether the output signal is output from the first output circuit, based on the driving control signal, wherein the output signal and the carry signal are generated using different voltage swing range.

### BRIEF DESCRIPTION OF THE DRAWINGS

The above and other aspects and features of certain embodiments will be more apparent from the following description taken in conjunction with the accompanying drawings, in which:

FIGS. 1 and 2 are diagrams schematically illustrating a display device, according to an embodiment;

FIG. 3 is a diagram schematically illustrating a driving circuit, according to an embodiment;

FIG. 4 is a diagram schematically illustrating input/output signals of a driving circuit, according to an embodiment;

FIG. 5 is a diagram illustrating any one of a plurality of stages included in the driving circuit of FIG. 3;

FIGS. 6A and 6B are timing diagrams for describing an operation of the stage of FIG. 5;

FIG. 7 is a diagram illustrating any one of a plurality of stages included in the driving circuit of FIG. 3;

FIGS. 8 and 9 are diagrams for describing a driving frequency for each area of a display device, according to an embodiment;

FIG. 10 is a diagram schematically illustrating a driving circuit, according to an embodiment;

FIG. 11A to 11C are diagrams illustrating any one of a plurality of stages included in the driving circuit of FIG. 10;

FIGS. 12A to 13B are timing diagrams for describing an operation of the stage of FIGS. 11A to 11C;

FIGS. 14A and 14B are diagrams illustrating a selection control signal CS and an output of a driving circuit for each frame in a second driving mode, according to an embodiment;

FIGS. 15 and 16 are diagrams illustrating any one of a plurality of stages included in the driving circuit of FIG. 10, according to an embodiment;

FIG. 17 is a block diagram illustrating an electronic device, according to an embodiment;

FIG. 18 is a schematic view illustrating electronic devices, according to various embodiments; and

FIG. 19 is a block diagram illustrating an electronic device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

“A and/or B” is used herein to select only A, select only B, or select both A and B. Also, “at least one of A and B” is used herein to select only A, select only B, or select both A and B.

In the following embodiments, when X and Y are connected to each other, it may include a case where X and Y are physically connected to each other, a case where X and Y are functionally connected to each other, and a case where X and Y are electrically connected to each other. Also, when X and Y are connected to each other, it may include a case where X and Y are directly connected to each other and a case where X and Y are indirectly connected to each other with other components therebetween. Here, X and Y may be components (e.g., apparatuses, devices, circuits, wirings, electrodes, terminals, films, layers, and regions).

For example, when X and Y are electrically connected to each other, it may include a case where X and Y are directly connected and electrically connected to each other and/or a case where X and Y are indirectly electrically connected to each other with other components therebetween. When X and Y are indirectly electrically connected, it may include a case where one or more elements (e.g., switches, transistors, capacitors, inductors, resistors, or diodes) that enable electrical connection between X and Y are connected between X and Y. Accordingly, a connection relationship is not limited to a certain connection relationship, for example, a connection relationship shown in the drawings or the detailed description, and may include other connection relationships than the connection relationship shown in the drawings or the detailed description.

In the following embodiments, the term “on” used in association with a device state may refer to a state in which a device is activated, and the term “off” may refer to a state in which a device is deactivated. The term “on” used in association with a signal received by a device may refer to a signal for activating the device, and the term “off” may refer to a signal for deactivating the device. A device may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-channel transistor and the N-channel transistor have opposite (low and high) voltage levels. Hereinafter, a voltage for activating (turning on) a transistor is referred to as a gate-on voltage, and a voltage for deactivating (turning off) a transistor is referred to as a gate-off voltage.

Embodiments relate to a driving circuit for a display device and an electronic device that includes the display device. Each stage of the driving circuit may include an input circuit, a first output circuit for outputting a signal to a signal line, a second output circuit for outputting a carry signal to the next stage, and a control circuit. Each stage of the driving circuit may further include a selection circuit. The input circuit may receive a start signal and drive internal nodes that control operation of the output circuits. The control circuit may manage voltage levels applied to the gates of transistors used for output signal generation, ensuring stable signal transitions. A separation of the output signal and the carry signal generation paths may allow for tailored voltage swings for each. The output signal may transition between a first voltage as its high level and a second voltage as its low level. In contrast, the carry signal may use the same first voltage as its high level but a third, lower voltage as its low level. This configuration may increases the swing width of the carry signal relative to the output signal, enhancing reliability in low-voltage operation.

In an embodiment, each stage includes a carry buffer and a multi-frequency driving control circuit, enabling the circuit to support multi-frequency driving. This may allow different display regions to be driven at different refresh rates, reducing power consumption by lowering the frequency in areas of the display that do not require high-speed updates. The inclusion of selection logic further allows for selective gate signal output, providing fine-grained control over which parts of the display are refreshed at which times. Thus, a stage-based driving architecture is provided that enhances signal stability, enables efficient multi-frequency operation, and supports robust gate signal generation across a wide range of operating conditions.

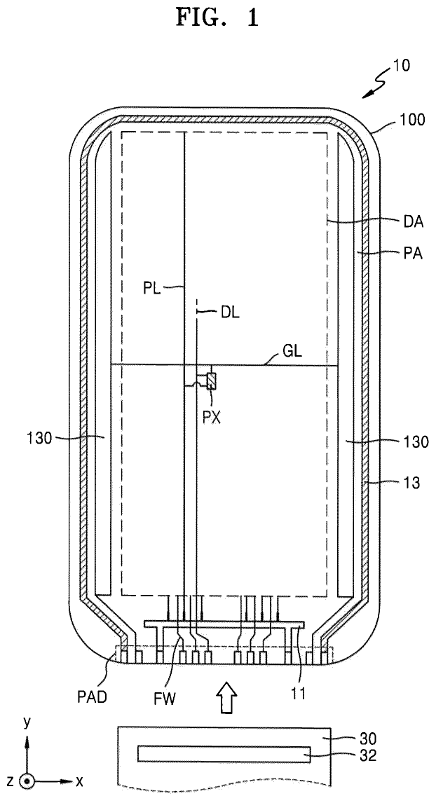

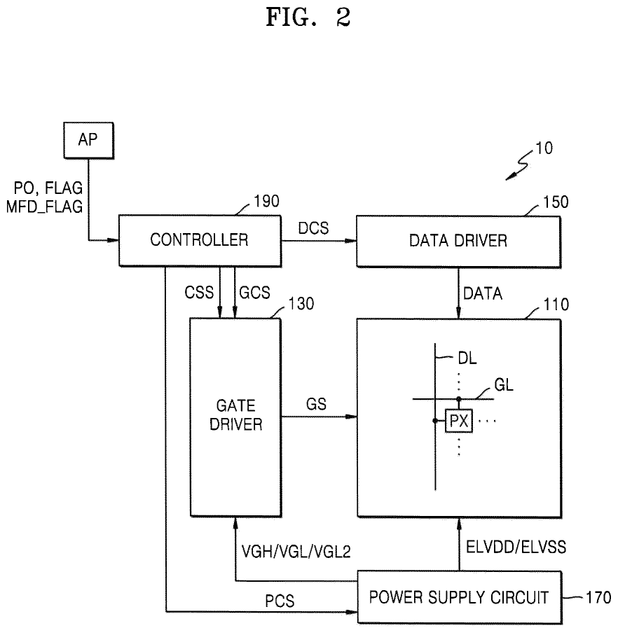

FIGS. 1 and 2 are diagrams schematically illustrating a display device, according to an embodiment.

A display device 10 is a device for displaying a moving image or a still image and may visually provide information to a user. The display device 10 according to an embodiment may be a display device such as an organic light-emitting display device, an inorganic light-emitting display device (or an inorganic electroluminescent (EL) display device), or a quantum dot light-emitting display device.

Referring to FIGS. 1 and 2, the display device 10 may include a display area DA and a peripheral area (non-display area) PA. The display device 10 may include a display panel 110. The display panel 110 includes a substrate 100, and a plurality of gate lines GL, a plurality of data lines DL, and a plurality of pixels PX connected to the gate lines GL and the data lines DL may be disposed in the display area DA of the substrate 100.

The plurality of pixels PX may be repeatedly arranged in a first direction (an x-direction or a row direction) and a second direction (a y-direction or a column direction). The plurality of pixels PX may be arranged in any of various forms, such as a stripe arrangement, a pentile arrangement, a diamond arrangement, or a mosaic arrangement, to display an image. Each of the plurality of pixels PX may include an organic light-emitting diode as a display element, and the organic light-emitting diode may be connected to a pixel circuit. The pixel circuit may include a plurality of transistors and at least one capacitor. Each pixel PX may emit light, for example, red light, green light, blue light, or white light, through the organic light-emitting diode OLED. Each pixel PX may be connected to a corresponding gate line from among the plurality of gate lines GL and a corresponding data line from among the plurality of data lines DL.

In an embodiment, the plurality of transistors included in the pixel circuit may be P-channel silicon transistors. In an embodiment, the plurality of transistors included in the pixel circuit may be N-channel oxide transistors. In an embodiment, some of the plurality of transistors included in the pixel circuit may be P-channel silicon transistors and the others may be N-channel oxide transistors.

Each of the gate lines GL may extend in the x-direction (row direction) and may be connected to the pixels PX located in the same row. Each of the gate lines GL may transmit a gate signal to the pixels PX in the same row. Each of the data lines DL may extend in the y-direction (column direction) and may be connected to the pixels PX arranged in the same column. Each of the data lines DL may transmit a data signal to each of the pixels PX in the same column in synchronization with a gate signal.

In the peripheral area (non-display area) PA outside or adjacent the display area DA of the display panel 110, various conductive lines for transmitting an electrical signal to be applied to the display area DA, outer driving circuits electrically connected to pixel circuits, and a terminal unit PAD where pads to which a printed circuit board or a driver integrated circuit (IC) chip is attached are located may be disposed. The terminal unit PAD may be exposed without being covered by an insulating layer, and may be connected to a display circuit board 30. A display driver 32 may be disposed on the display circuit board 30. The display driver 32 may include a data driver 150 (e.g., a driver circuit), a power supply circuit 170, and a controller 190 (e.g., a controller circuit).

In an embodiment, a gate driver 130 (e.g., a driver circuit), the data driver 150, the power supply circuit 170, and the controller 190 may be mounted as driving chips on the display panel 110. The data driver 150, the power supply circuit 170, and the controller 190 may be formed as separate IC chips or may be formed as one IC chip and may be disposed on a flexible printed circuit board (FPCB) electrically connected to a pad disposed on a side of the substrate constituting the display panel 110. In another embodiment, the data driver 150, the power supply circuit 170, and the controller 190 may be directly disposed on the substrate in a chip-on-glass (COG) or chip-on-plastic (COP) manner.

The gate driver 130 may be connected to the plurality of gate lines GL, may generate gate signals GS in response to a gate driving control signal GCS from the controller 190, and may sequentially supply the gate signals GS to the gate lines GL. The gate line GL may be connected to a gate of a transistor included in the pixel PX, and the gate signal GS may be a gate control signal for controlling turn-on and turn-off of the transistor to which the gate line is connected. The gate signal GS may include a gate-on voltage for turning on a transistor and a gate-off voltage for tuning off the transistor. In an embodiment, the gate driving control signal GCS may include a start signal and a plurality of clock signals.

In an embodiment, the pixel circuits of the pixels PX of the display area DA may be electrically connected to a left gate driver 130 and a right gate driver 130. One of the left gate driver 130 and the right gate driver 130 may be omitted.

The gate driver 130 may include a plurality of stages for sequentially generating and outputting the gate signals GS. The number of stages constituting the gate driver 130 according to an embodiment may change in various ways according to the number of rows (horizontal lines) provided on the display panel 110.

The data driver 150 may be connected to the plurality of data lines DL and may generate a data signal DATA in response to a data driving control signal DCS from the controller 190. The data signal DATA may be transmitted to the pixel circuits of the pixels PX through a fan-out line FW and the data line DL connected to the fan-out line FW. The data signal DATA input to the data lines DL may be input to the pixels PX to which the gate signal is input. The data driver 150 may convert input image data having a gray level input from the controller 190 into the data signal DATA in the form of a voltage or current. In an embodiment, the data driving control signal DCS may include a start signal and a plurality of clock signals.

The power supply circuit 170 may generate signals (voltages and current) used to drive the pixels PX in response to a power driving control signal PCS from the controller 190.

When the display device 10 is an organic light-emitting display device, the power supply circuit 170 may supply a first power supply voltage ELVDD to a driving voltage supply line 11 and may supply a second power supply voltage ELVSS to a common voltage supply line 13. The first power supply voltage ELVDD may be applied to the pixel circuits of the pixels PX through a driving voltage line PL connected to the driving voltage supply line 11, and the second power supply voltage ELVSS may be applied to a counter electrode of a display element through the common voltage supply line 13. The first power supply voltage ELVDD may be a high-level voltage provided to one terminal of a driving transistor connected to a first electrode (a pixel electrode or an anode) of the organic light-emitting diode of each pixel PX. The second power supply voltage ELVSS may be a low-level voltage provided to a second electrode (a counter electrode or a cathode) of the organic light-emitting diode. The first power supply voltage ELVDD and the second power supply voltage ELVSS may be driving voltages for causing the plurality of pixels PX to emit light.

The power supply circuit 170 may generate a high-level voltage VGH and low-level voltages VGL and VGL2 and may supply the high-level voltage VGH and the low-level voltages VGL and VGL2 to the gate driver 130.

The controller 190 may generate the gate driving control signal GCS, the data driving control signal DCS, and the power driving control signal PCS based on signals input from the outside. The controller 190 may supply the gate driving control signal GCS to the gate driver 130, may supply the data driving control signal DCS to the data driver 150, and may supply the power driving control signal PCS to the power supply circuit 170.

In an embodiment, the display device 10 may be connected to a processor of an electronic device. The processor may include an application processor AP. The controller 190 may receive an on-operation signal, for example, a power-on signal PO and/or an operation flag signal FLAG, from the application processor AP. When the electronic device is powered on or is awakened from a sleep mode by the user, the controller 190 may receive an on-operation signal from the application processor AP, and may generate and output the gate driving control signal GCS, the data driving control signal DCS, and the power driving control signal PCS based on the on-operation signal. The gate driver 130 receiving the gate driving control signal GCS may operate at a timing according to at least one embodiment described below.

In an embodiment, the controller 190 may receive a multi-frequency driving flag signal MFD_FLAG from the application processor AP. The controller 190 may output a multi-frequency driving control signal CSS to the gate driver 130 based on the multi-frequency driving flag signal MFD_FLAG. The gate driver 130 may receive the multi-frequency driving control signal CSS to operate in a multi-frequency driving mode. In the multi-frequency driving mode, the gate driver 130 may control the output of the gate signal GS for each area, which will be described below in detail.

In an embodiment, a part or the whole of the gate driver 130 may be directly formed in the peripheral area of the substrate during a process of forming a transistor constituting a pixel circuit in the display area of the substrate. The gate driver 130 may include an amorphous silicon thin-film transistor (TFT) gate driver circuit (ASG), a low-temperature polycrystalline silicon (LTPS) TFT gate driver circuit, or an oxide semiconductor TFT gate driver circuit (OSG), any may be integrated within the display panel 110.

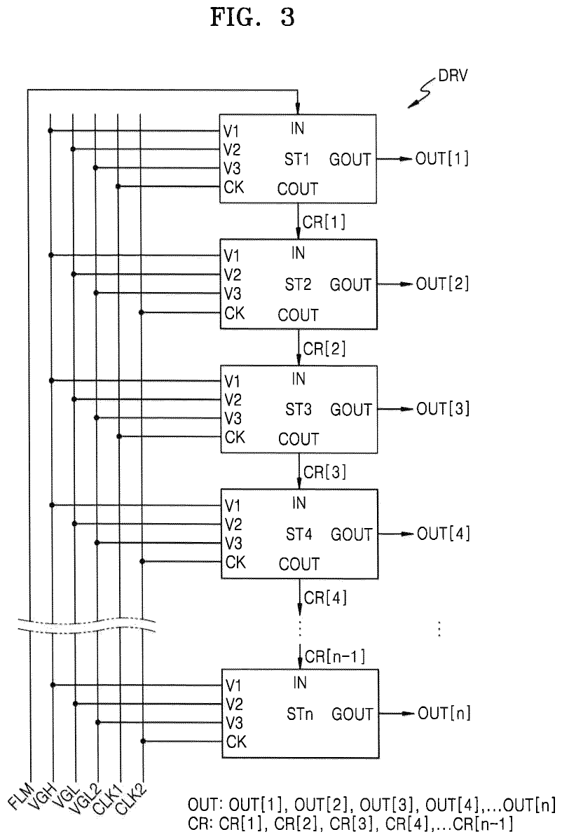

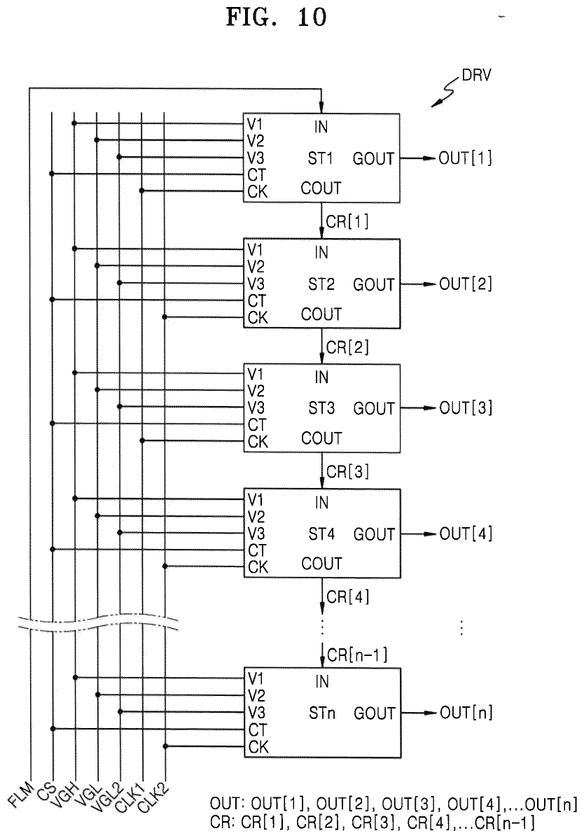

In an embodiment, the gate driver 130 may be implemented as a driving circuit DRV (see FIGS. 3 and 10) illustrated below. Output signals OUT (see FIGS. 3 and 10) output by the driving circuit DRV to output lines may correspond to the gate signals GS output by the gate driver 130 to the gate lines GL. Each of the plurality of stages may be connected to the gate line GL disposed in a corresponding row of the display panel 110. Each of the plurality of stages may generate the gate signal GS as the output signal OUT and output it to the corresponding connected gate line GL. That is, each of the stages may supply the gate signal GS to the gate line GL provided in a corresponding row. In an embodiment, the gate driving control signal GCS of FIG. 2 includes an external start signal FLM (see FIGS. 3 and 10) and a plurality of clock signals (e.g., CLK1 and CLK2) (see FIGS. 3 and 10).

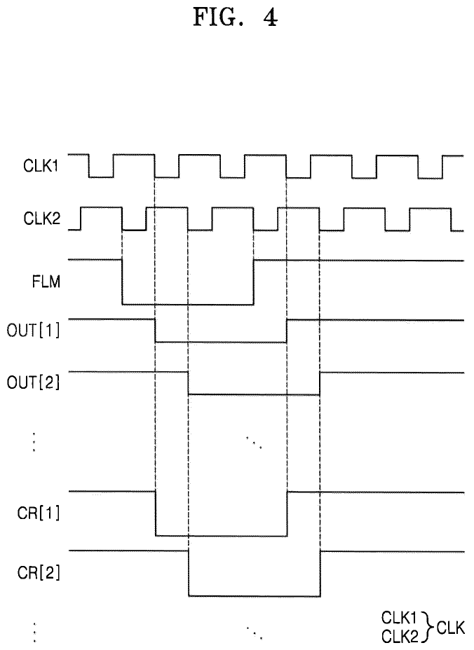

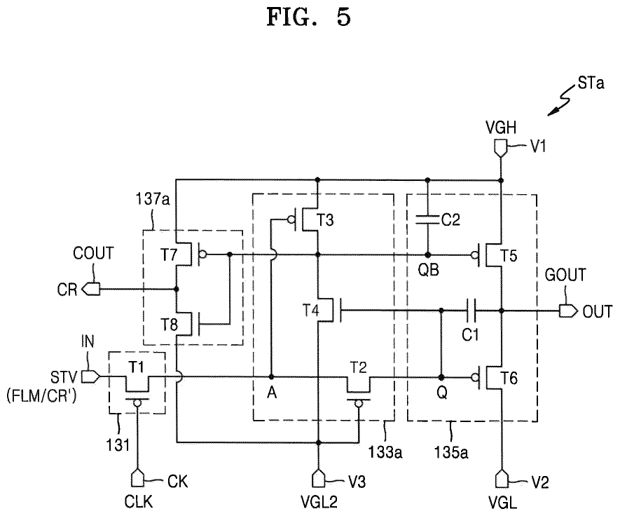

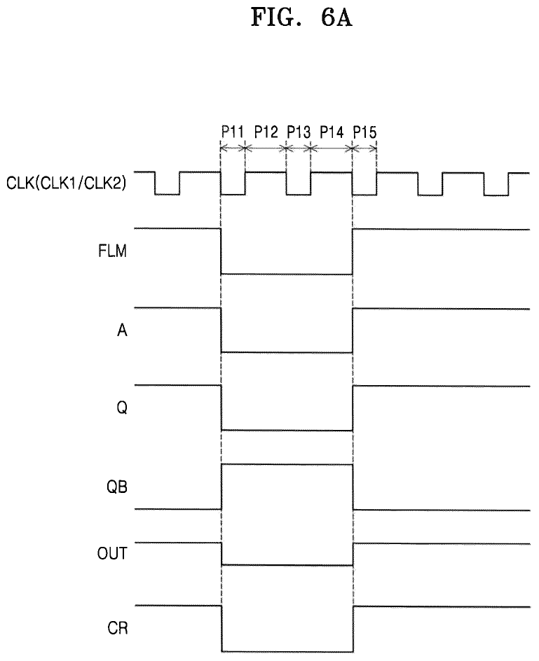

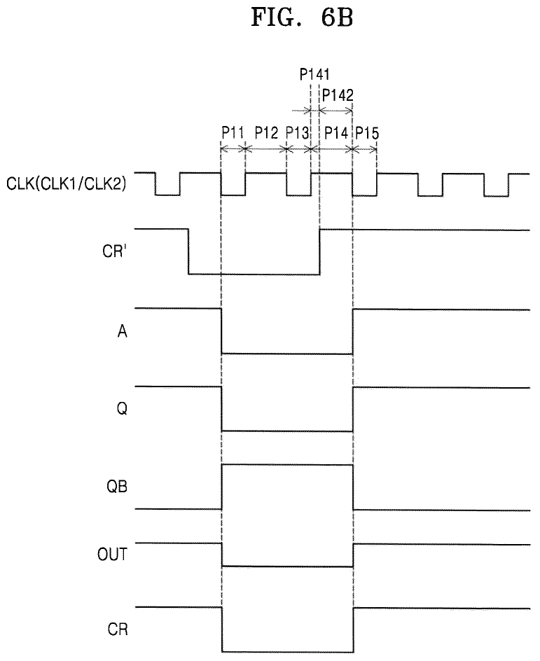

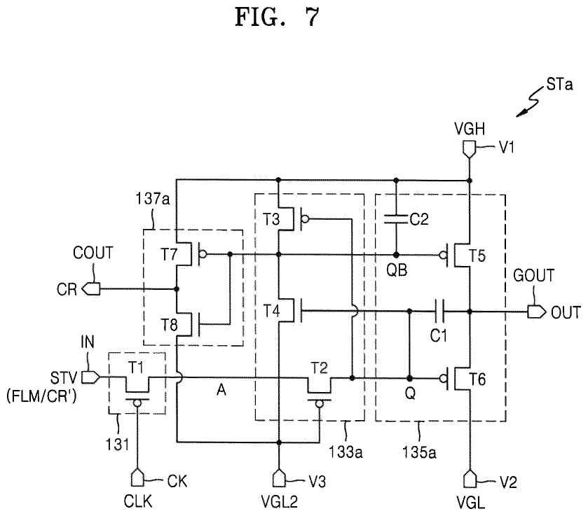

FIG. 3 is a diagram schematically illustrating a driving circuit, according to an embodiment. FIG. 4 is a diagram schematically illustrating input/output signals of a driving circuit, according to an embodiment. FIG. 5 is a diagram illustrating any one of a plurality of stages included in the driving circuit of FIG. 3. FIGS. 6A and 6B are timing diagrams for describing an operation of the stage of FIG. 5. FIG. 7 is a diagram illustrating any one of a plurality of stages included in the driving circuit of FIG. 3.

Referring to FIG. 3, a driving circuit DRV according to an embodiment may include a plurality of stages (e.g., ST1 to STn). Here, n is nature number greater than 1The plurality of stages (e.g., ST1 to STn) may sequentially output output signals (e.g., OUT[1], OUT[2], OUT[3], OUT[4], . . . , and OUT[n]) to signal lines. Each of the stages (e.g., ST1 to STn) may be connected to a signal line. Each of the stages (e.g., ST1 to STn) may receive at least one clock signal and at least one voltage signal, may generate an output signal OUT and output it to a connected signal line.

The plurality of stages (e.g., ST1 to STn) may respectively output output signals (e.g., OUT[1], OUT[2], OUT[3], OUT[4], . . . , and OUT[n]) in response to a start signal STV (see FIG. 5). The start signal STV may be an external start signal FLM or any of carry signals CR[1], CR[2], CR[3], CR[4], . . . , and CR[n−1]. For example, the external start signal FLM that is a start signal for controlling a timing of a first output signal OUT[1] may be supplied to a first stage ST1, and the first stage ST1 may output the first output signal OUT[1] to a first signal line. An n^{th} stage STn may receive the carry signal CR[n−1] output by an n−1^{th} stage as a start signal, and may output an n^{th} output signal OUT[n] to an n^{th} signal line.

Each of the stages (e.g., ST1 to STn) may include a plurality of terminals to receive (or input) and transmit (or output) a plurality of signals. The plurality of signals may include a clock signal and a voltage signal. The plurality of terminals may include an input terminal IN, a first voltage input terminal V1, a second voltage input terminal V2, a third voltage input terminal V3, a clock terminal CK, a first output terminal GOUT, and a second output terminal COUT.

The start signal STV may be input (supplied) to the input terminal IN. The external start signal FLM may be input as the start signal STV to the input terminal IN of the first stage ST1, and a carry signal output from a previous stage (hereinafter, referred to as a ‘previous carry signal’) CR′ (see FIG. 5) may be input as the start signal STV to the input terminal IN of each of second to n^{th} stages ST2 to STn. A previous stage may be a stage located at least one before a current stage. In FIG. 3, a previous stage is a stage located immediately before a current stage. For example, the carry signal CR[2] output by the second stage ST2 may be input as the start signal STV to the input terminal IN of the third stage ST3.

A first voltage VGH may be input to the first voltage input terminal V1, a second voltage VGL may be input to the second voltage input terminal V2, and a third voltage VGL2 may be input to the third voltage input terminal V3. In an embodiment, the second voltage VGL is less than the first voltage VGH, and the third voltage VGL2 is less than the second voltage VGL. Hereinafter, the first voltage VGH is described as a high-level voltage, and the second voltage VGL and the third voltage VGL2 are described as low-level voltages. In an embodiment, the high-level voltage may be a (+) voltage (or positive voltage), and the low-level voltage may be a (−) voltage (or negative voltage).

A clock signal CLK may be input to the clock terminal CK. The clock signal CLK may include a first clock signal CLK1 and a second clock signal CLK2. The first clock signal CLK1 or the second clock signal CLK2 may be input to the clock terminal CK. In an embodiment, the first clock signal CLK1 may be input to the clock terminals CK of odd-numbered stages (e.g., ST1, ST3, . . . ) and the second clock signal CLK2 may be input to the clock terminals CK of even-numbered stages (e.g., ST2, ST4, . . . ). In an embodiment, the second clock signal CLK2 may be input to the clock terminals CK of the odd-numbered stages (e.g., ST1, ST3, . . . ) and the first clock signal CLK1 may be input to the clock terminals CK of the even-numbered stages (e.g., ST2, ST4, . . . ).

As shown in FIG. 4, the first clock signal CLK1 and the second clock signal CLK2 may be signals in which a high-level voltage and a low-level voltage are periodically repeated. In an embodiment, the first clock signal CLK1 and the second clock signal CLK2 may be alternating signals that swing between the first voltage VGH and the second voltage VGL in a repeated manner. The first clock signal CLK1 and the second clock signal CLK2 may share the same waveform but be phase-shifted relative to each other. For example, the second clock signal CLK2 may have the same waveform as the first clock signal CLK1 and may be input to a corresponding stage with its phase shifted (delayed) at certain intervals. The second clock signal CLK2 may be half (½) period shifted with respect to the first clock signal CLK1. In the first clock signal CLK1 and the second clock signal CLK2, a duration during which a high-level voltage is maintained for one period may be the same as or longer than a duration during which a low-level voltage is maintained.

An output signal may be output from the first output terminal GOUT. As shown in FIG. 4, the output signals (e.g., OUT[1], OUT[2], OUT[3], OUT[4], . . . , and OUT[n]) output from the first output terminals GOUT of the stages (e.g., ST1 to STn) may be sequentially shifted by a certain time. In an embodiment, the stages (e.g., ST1 to STn) may shift the output signals (e.g., OUT[1], OUT[2], OUT[3], OUT[4], . . . , and OUT[n]) of a low-level voltage by ½ period of a clock signal and may sequentially output the output signals (e.g., OUT[1], OUT[2], OUT[3], OUT[4], . . . , and OUT[n]). In an embodiment, a high-level voltage and a low-level voltage of output signals may be respectively the first voltage VGH and the second voltage VGL.

A carry signal may be output from the second output terminal COUT. As shown in FIG. 4, the carry signals CR[1], CR[2], CR[3], CR[4], . . . , and CR[n−1] output from the second output terminals COUT of the stages (e.g., ST1 to STn) may be sequentially shifted in time by a predetermined interval. In an embodiment, the stages (e.g., ST1 to STn) may shift the carry signals CR[1], CR[2], CR[3], CR[4], . . . , and CR[n−1] of a low-level voltage by ½ period of a clock signal and may sequentially output the carry signals CR[1], CR[2], CR[3], CR[4], . . . , and CR[n−1]. In an embodiment, a high-level voltage and a low-level voltage of carry signals may be respectively the first voltage VGH and the third voltage VGL2. A voltage swing between high-level and low-level voltages of carry signals may be greater than a voltage swing between a high-level voltage and a low-level voltage of output signals.

FIG. 5 illustrates an arbitrary stage STa among the stages (e.g., ST1 to STn). The stage STa may be an odd-numbered stage or an even-numbered stage. The start signal STV (e.g., the external start signal FLM or the previous carry signal CR′) may be input to the input terminal IN of the stage STa. The clock signal CLK (e.g., the first clock signal CLK1 or the second clock signal CLK2) may be input to the clock terminal CK of the stage STa.

The stage STa may include a logic circuit and an output circuit. As shown in FIG. 5, the logic circuit may include an input circuit 131 and a control circuit 133a, and the output circuit may include a first output circuit 135a and a second output circuit 137a. Each of the input circuit 131, the control circuit 133a, the first output circuit 135a, and the second output circuit 137a may include at least one transistor. The at least one transistor may include an N-channel transistor and/or a P-channel transistor. For example, a fourth transistor T4 and an eighth transistor T8 may be N-channel transistors, and a first transistor T1, a second transistor T2, a third transistor T3, a fifth transistor T5, a sixth transistor T6, and a seventh transistor T7 may be P-channel transistors.

A P-channel transistor may be a P-channel silicon transistor. The silicon transistor may include a silicon semiconductor, and the silicon semiconductor may include amorphous silicon or polysilicon. For example, the silicon transistor may be a low-temperature polycrystalline silicon (LTPS) thin-film transistor.

An N-channel transistor may be an N-channel oxide transistor. The oxide transistor may include an oxide semiconductor, and the oxide semiconductor may include a Zn oxide-based material such as Zn oxide, In—Zn oxide, or Ga—In—Zn oxide. In some embodiments, the oxide semiconductor may be an In—Ga—Zn—O (IGZO) semiconductor. In some embodiments, the oxide semiconductor may be an In—Sn—Ga—Zn—O (ITGZO) semiconductor. For example, the oxide transistor may be a low-temperature polycrystalline oxide (LTPO) thin-film transistor.

The input circuit 131 may transmit the start signal STV to a first node A in response to the clock signal CLK input to the clock terminal CK. The input circuit 131 may include the first transistor T1.

The first transistor T1 may be connected between the input terminal IN and the first node A. A gate of the first transistor T1 may be connected to the clock terminal CK. The first transistor T1 may be turned on when the clock signal CLK input to the clock terminal CK is at a low level, allowing the start signal STV received at the input terminal IN to be transmitted to the first node A. In an embodiment, when the start signal STV is a low-level voltage, a voltage of the first node A may be higher than the low-level voltage of the start signal STV due to threshold voltage loss of the first transistor T1.

The control circuit 133a may control voltages of a second node Q and a third node QB according to a voltage of the first node A. For example, the control circuit 133a may control voltages of the second node Q and the third node QB according to a voltage of a signal transmitted to the first node A through the first transistor T1. The control circuit 133a may include the second to fourth transistors T2 to T4.

The second transistor T2 may be connected between the first node A and the second node Q. A gate of the second transistor T2 may be connected to the third voltage input terminal V3. The second transistor T2 may be turned on by the third voltage VGL2 supplied to the third voltage input terminal V3, enabling the start signal STV transmitted through the first transistor T1 to be passed to the second node Q.

The third transistor T3 may be connected between the first voltage input terminal V1 and the third node QB. A gate of the third transistor T3 may be connected to the first node A as shown in FIG. 5, or may be connected to the second node Q as shown in FIG. 7. The third transistor T3 may be turned on when a voltage at the first node A or the second node Q is at a low level, allowing the first voltage VGH supplied to the first voltage input terminal V1 to be transmitted to the third node QB. Due to the third transistor T3, a voltage of the third node QB may be a voltage of a voltage level obtained by inverting a voltage level of the first node A or the second node Q.

The fourth transistor T4 may be connected between the third node QB and the third voltage input terminal V3. A gate of the fourth transistor T4 may be connected to the second node Q. The fourth transistor T4 may be turned on when a signal at the second node Q is a high-level voltage, allowing the third voltage VGL2 supplied to the third voltage input terminal V3 to be transmitted to the third node QB. Due to the fourth transistor T4, a voltage of the third node QB may be a voltage of a voltage level obtained by inverting a voltage level of the second node Q.

The third transistor T3 and the fourth transistor T4 may control a voltage level of the third node QB according to a voltage level of the first node A or the second node Q, and thus, may function as inverters or level shifters. In an embodiment, channel types of the third transistor T3 and the fourth transistor T4 are different from each other. For example, one may be P-channel while the other is N-channel

The first output circuit 135a may be connected between the first voltage input terminal V1 and the second voltage input terminal V2. The first output circuit 135a may output the output signal OUT of a high-level voltage or a low-level voltage according to voltages of the second node Q and the third node QB. The first output circuit 135a may include the fifth transistor T5 and the sixth transistor T6. The first output circuit 135a may further include a first capacitor C1 and a second capacitor C2.

The fifth transistor T5 may be connected between the first voltage input terminal V1 and the first output terminal GOUT. A gate of the fifth transistor T5 may be connected to the third node QB. The fifth transistor T5 may be a pull-up transistor that transmits a high-level voltage to the first output terminal GOUT. The fifth transistor T5 may be turned on when a voltage of the third node QB is at a low level, allowing the high-level first voltage VGH supplied to the first voltage input terminal V1 to be transmitted to the first output terminal GOUT.

The sixth transistor T6 may be connected between the first output terminal GOUT and the second voltage input terminal V2. A gate of the sixth transistor T6 may be connected to the second node Q. The sixth transistor T6 may be a pull-down transistor that transmits a low-level voltage to the first output terminal GOUT. The sixth transistor T6 may be turned on when a voltage of the second node Q is at a low level, allowing the low-level second voltage VGL supplied to the second voltage input terminal V2 to be transmitted to the first output terminal GOUT.

The first capacitor C1 may be connected between the first output terminal GOUT and the second node Q. The second capacitor C2 may be connected between the first voltage input terminal V1 and the third node QB. The first capacitor C1 may maintain a voltage of the second node Q, and the second capacitor C2 may maintain a voltage of the third node QB. The first capacitor C1 may change a voltage of the second node Q in accordance with a voltage change of the first output terminal GOUT.

The second output circuit 137a may be connected between the first voltage input terminal V1 and the third voltage input terminal V3. The second output circuit 137a may output the carry signal CR of a high-level voltage or a low-level voltage according to a voltage of the third node QB. The second output circuit 137a may include the seventh transistor (a second pull-up transistor) T7 and the eighth transistor (a second pull-down transistor) T8. In an embodiment, channel types of the third transistor T7 and the fourth transistor T8 are different from each other.

The seventh transistor T7 may be connected between the first voltage input terminal V1 and the second output terminal COUT. A gate of the seventh transistor T7 may be connected to the third node QB. The seventh transistor T7 may be a pull-up transistor that transmits a high-level voltage to the second output terminal COUT. The seventh transistor T7 may be turned on when a voltage of the third node QB is at a low level, allowing the high-level first voltage VGH supplied to the first voltage input terminal V1 to be transmitted to the second output terminal COUT.

The eighth transistor T8 may be connected between the second output terminal COUT and the third voltage input terminal V3. A gate of the eighth transistor T8 may be connected to the third node QB. The eighth transistor T8 may be a pull-down transistor that transmits a low-level voltage to the second output terminal COUT. The eighth transistor T8 may be turned on when a voltage of the third node QB is at a high level, allowing the low-level third voltage VGL2 supplied to the third voltage input terminal V3 to be transmitted to the second output terminal COUT.

An operation of the stage STa of FIG. 5 will be described with reference to FIGS. 6A and 6B. FIG. 6A is a timing diagram for describing an operation of the stage of FIG. 4 when a start signal is the external start signal FLM. FIG. 6B is a timing diagram for describing an operation of the stage of FIG. 4 when a start signal is the previous carry signal CR′.

A low-level voltage input to a gate of a P-channel transistor may be defined as a gate-on voltage, and a high-level voltage may be defined as a gate-off voltage. A high-level voltage input to a gate of an N-channel transistor may be defined as a gate-on voltage, and a low-level voltage may be defined as a gate-off voltage.

In FIGS. 6A and 6B, the external start signal FLM or the previous carry signal CR′ as the start signal STV input to the input terminal IN, the first clock signal CLK1 or the second clock signal CLK2 as the clock signal CLK input to the clock terminal CK, voltages of the first to third nodes A, Q, and QB, the output signal OUT, and the carry signal CR are illustrated.

A low-level voltage of the clock signal CLK may be the second voltage VGL, and a high-level voltage of the clock signal CLK may be the first voltage VGH. A low-level voltage of the external start signal FLM may be the third voltage VGL2, and a high-level voltage of the external start signal FLM may be the first voltage VGH. A low-level voltage of the carry signal CR and the previous carry signal CR′ may be the third voltage VGL2, and a high-level voltage of the carry signal CR and the previous carry signal CR′ may be the first voltage VGH. A low-level voltage of the output signal OUT may be the second voltage VGL, and a high-level voltage of the output signal OUT may be the first voltage VGH.

In a first interval P11, the clock signal CLK of a low level may be input to the clock terminal CK, and the start signal STV of a low level (e.g., the external start signal FLM of FIG. 6A or the previous carry signal CR′ of FIG. 6B) may be input to the input terminal IN.

The first transistor T1 may be turned on by the clock signal CLK of a low level, and the start signal STV of a low level may be transmitted to the first node A by the first transistor T1 that is turned on. In an embodiment, a voltage of the first node A may be a third voltage that is a low-level voltage of the start signal STV. In an embodiment, a voltage of the first node A is higher than the third voltage VGL2, which is a low-level voltage of the start signal STV, by a magnitude (absolute value) of a threshold voltage Vth_t1 of the first transistor T1 due to threshold voltage loss of the first transistor T1.

The second transistor T2 may be turned on by the third voltage VGL2 of a low level, which is a gate voltage of the second transistor T2, and a signal of the first node A may be transmitted to the second node Q by the second transistor T2 that is turned on. A voltage of the second node Q may be reduced to a level of the first node A, causing the second transistor T2 to function as a reverse-biased diode.

The sixth transistor T6 with its gate connected to the second node Q may be turned on, allowing the low-level second voltage VGL to be transmitted to the first output terminal GOUT through the turned on sixth transistor T6. Accordingly, the output signal OUT may be the second voltage VGL of a low level. In this case, as a voltage of the first output terminal GOUT is reduced from a high-level voltage to a low-level voltage, a voltage of the second node Q may be boosted downward due to a coupling effect of the first capacitor C1 and may be further reduced by a voltage change amount (ΔV=first voltage VGH—second voltage VGL) of the first output terminal GOUT. In an embodiment, after the downward boosting, a voltage of the second node Q may be approximately a value (VGL2−Vth_t1−ΔV) obtained by subtracting the threshold voltage Vth_t1 of the first transistor T1 and the voltage change amount ΔV of the first output terminal GOUT from the third voltage VGL2.

The third transistor T3 with its gate connected to the first node A may be turned on, allowing the fourth transistor T4 with its gate connected to the second node Q to be turned off. The first voltage VGH of a high level may be transmitted to the third node QB by the third transistor T3 that is turned on, and a voltage of the third node QB may be the first voltage VGH of a high level. The fifth transistor T5 with its gate connected to the third node QB may be turned off.

The seventh transistor T7 with its gate connected to the third node QB may be turned off, while the eighth transistor T8 may be turned on. The third voltage VGL2 of a low level may be transmitted to the second output terminal COUT by the eighth transistor T8 that is turned on. Accordingly, the carry signal CR may be the third voltage VGL2 of a low level.

In a second interval P12, the clock signal CLK of a high level may be input to the clock terminal CK, and the start signal STV of a low level may be input to the input terminal IN.

The first transistor T1 may be turned off by the clock signal CLK of a high level, and a voltage of the first node A may maintain a low level voltage of the first interval P11. A voltage of the second node Q may maintain a low-level voltage of the first interval P1 due to the second transistor T2 that is turned off.

The sixth transistor T6 with its gate connected to the second node Q may maintain a turn-on state, and thus, the output signal OUT from the first output terminal GOUT may be continuously output as the second voltage VGL of a low level.

The third transistor T3 with its gate connected to the first node A may maintain a turn-on state, the fourth transistor T4 with the gate connected to the second node Q may maintain a turn-off state, and a voltage of the third node QB may maintain a high-level voltage of the first interval P11. The fifth transistor T5 with its gate connected to the third node QB may maintain a turn-off state.

The seventh transistor T7 with its gate connected to the third node QB may maintain a turn-off state, and the eighth transistor T8 may maintain a turn-on state. Accordingly, the carry signal CR may maintain a low-level voltage of the first interval P11.

In a third interval P13, the start signal STV of a low level may be input to the input terminal IN, and the clock signal CLK of a low level may be input to the clock terminal CK.

Although the first transistor T1 is turned on by the clock signal CLK of a low level, because the start signal STV is at a low level, a voltage of each of the first node A, the second node Q, and the third node QB may maintain a voltage of a previous interval (e.g., the second interval P12).

When the start signal STV is the external start signal FLM, in a fourth interval P14, the external start signal FLM of a low level may be input to the input terminal IN and the clock signal CLK of a high level may be input to the clock terminal CK. When the start signal STV is the previous carry signal CR′, in the fourth interval P14, the clock signal CLK of a high level may be input to the clock terminal CK, in a 4-1 interval P141 of the fourth interval P14, the previous carry signal CR′ of a low level may be input to the input terminal IN, and in a 4-2 interval P142 of the fourth interval P14, the previous carry signal CR′ of a high level may be input to the clock terminal CK.

Because the first transistor T1 is turned off by the clock signal CLK of a high level, the voltages at the first node A, the second node Q, and the third node QB may remain at the levels held during a previous interval (e.g., the third interval P13), regardless of the voltage level of the start signal STV.

Th sixth transistor T6 with its gate connected to the second node Q may maintain a turn-on state, and thus, the output signal OUT from the first output terminal GOUT may be continuously output as the second voltage VGL of a low level.

The fifth transistor T5 and the seventh transistor T7, with their gates connected to the third node QB, may remain in a turned-off state, while the eighth transistor T8 may remain in a turned-on state. Accordingly, the carry signal CR may maintain a low-level voltage of the third interval P13.

In a fifth interval P15, the clock signal CLK of a low level may be input to the clock terminal CK, and the start signal STV of a high level may be input to the input terminal IN.

The start signal STV of a high level may be transmitted to the first node A by the first transistor T1 that is turned on by the clock signal CLK of a low level. A voltage of the first node A may be the first voltage VGH that is a high-level voltage of the start signal STV.

The second transistor T2 may be turned on by the third voltage VGL2 of a low level applied to its gate, allowing a voltage of the first node A to be transmitted to the second node Q through the turned-on second transistor T2. A voltage of the second node Q may be the first voltage VGH that is a high-level voltage. The sixth transistor T6 with its gate connected to the second node Q may be turned off.

The third transistor T3 with its gate connected to the first node A may be turned off, and the fourth transistor T4 with its gate connected to the second node Q may be turned on. The third voltage VGL2 may be transmitted to the third node QB by the fourth transistor T4 that is turned on, resulting in the third node QB being set to the third voltage VGL2 of a low level.

The fifth transistor T5 with its gate connected to the third node QB may be turned on, and the first voltage VGH of a high level may be transmitted to the first output terminal GOUT by the fifth transistor T5 that is turned on. Accordingly, the output signal OUT may be the first voltage VGH of a high level.

The seventh transistor T7 with its gate connected to the third node QB may be turned on, while the eighth transistor T8 may be turned off. The first voltage VGH of a high level may be transmitted to the second output terminal COUT by the seventh transistor T7 that is turned on. Accordingly, the carry signal CR may be the first voltage VGH of a high level.

The stage STa of the driving circuit DRV according to an embodiment separately includes a circuit for outputting the output signal OUT and a circuit for outputting the carry signal CR, and may receive the carry signal CR as the input signal. Because a low-level voltage of the carry signal CR is less than a low-level voltage of the output signal OUT, a swing width between a high-level voltage and a low-level voltage of the carry signal CR may be greater than a swing width between a high-level voltage and a low-level voltage of the output signal OUT.

Because the stage STa receives the input signal of a low-level voltage lower than a low-level voltage of the output signal OUT and transmits it to the first node A and the second node Q, turn-on of the sixth transistor T6 can be ensured even in the presence of threshold voltage loss in the first transistor T1. Accordingly, a low-level voltage of the output signal OUT may be stably output. As a low-level voltage is stably output, the difference between the high-level and low-level voltages at the first output terminal GOUT may be maintained, minimizing any reduction in signal swing. Additionally, voltage drop at the second node Q due to capacitive coupling through the first capacitor C1 may be reduced.

The driving circuit DRV according to an embodiment may distinguish the output signal OUT from the carry signal CR, and may change a bias direction of the second transistor T2 whose gate receives the third voltage VGL2 according to a value of the third voltage VGL2, which serves as a low-level voltage of the carry signal CR. Accordingly, a degree of freedom of a voltage that may be transmitted to the first node A and the second node Q may increase.

Because the driving circuit DRV according to an embodiment implements a second output circuit for outputting the carry signal CR by using the seventh transistor T7 of a P-channel and the eighth transistor T8 of an N-channel, and connects a gate of the eighth transistor T8 to the third node QB, stable turn-on of the eighth transistor T8 may be ensured. Accordingly, the carry signal CR of a low level may be stably output.

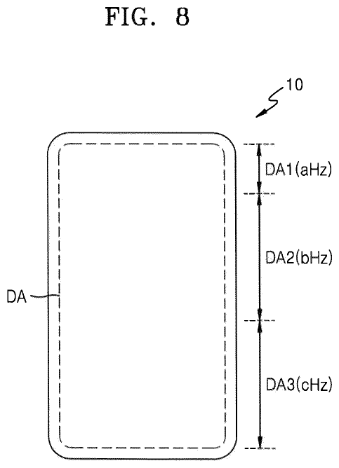

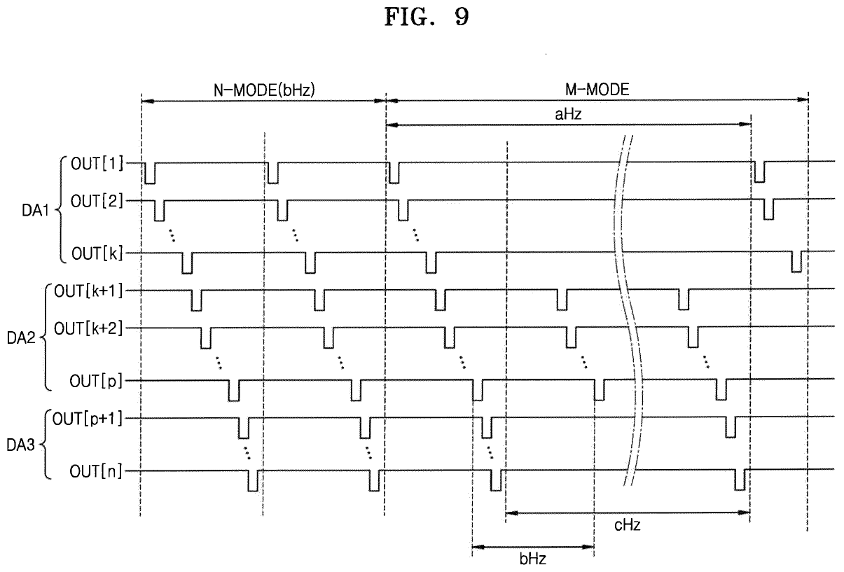

FIGS. 8 and 9 are diagrams for describing a driving frequency for each area of a display device, according to an embodiment.

Referring to FIG. 8, the display device 10 may display an image in a first driving mode or a second driving mode. In an embodiment, the first driving mode is a normal driving mode, and the second driving mode is a multi-frequency driving (MFD) mode.

In the first driving mode, the display device 10 may display an image in an entire display area at one driving frequency. For example, in the first driving mode, the display device 10 may simultaneously display an image at aHz (e.g., 10 Hz) in the entire display area DA, or display an image at bHz (e.g., 120 Hz) in the entire display area DA.

In the second driving mode, the display device 10 may display an image at different driving frequencies in a plurality of areas divided from the display area. For example, in the second driving mode, the display device 10 may simultaneously display an image at aHz (e.g., 10 Hz) in a first area DA1, display an image at bHz (e.g., 120 Hz) in a second area DA2, and display an image at cHz (e.g., 30 Hz) in a third area DA3.

As shown in FIG. 9, in the first driving mode N-MODE, the driving circuit DRV may sequentially output the output signal OUT to the first area DA1, the second area DA2, and the third area DA3 according to the driving frequency of bHz.

The driving circuit DRV may operate in the second driving mode M-MODE in response to the multi-frequency driving control signal CSS (see FIG. 2). In the second driving mode M-MODE, the driving circuit DRV may control the output of the output signal OUT for each area according to a driving frequency for each area. In the second driving mode M-MODE, the driving circuit DRV may output the output signal OUT in at least one area and does not output the output signal in another area according to a driving frequency for each area. For example, the driving circuit DRV may output the output signal OUT in a high-frequency area, and does not output the output signal OUT in a low-frequency area. For example, in the second driving mode M-MODE, the display area may be divided into two regions: a high-frequency area driven at 120 Hz and a low-frequency area driven at 30 Hz. The driving circuit may output the output signal in the 120 Hz region every frame, while suppressing the output signal in the 30 Hz region for three out of every four frames, effectively reducing power consumption in the low-frequency area. However, the driving frequencies are not limited to 120 Hz and 30 Hz and may be set to other values according to display requirements.

The driving circuit DRV may sequentially output output signals (a first output signal OUT[1] to a k^{th} output signal OUT[k]) according to a driving frequency of aHz in the first area DA1 (first to k^{th} rows), may sequentially output output signals (a k+1^{th} output signal OUT[k+1] to a p^{th} output signal OUT[p]) according to a driving frequency of bHz in the second area DA2 (k+1^{th} to p^{th} rows), and may sequentially output output signals (a p+1^{th} output signal OUT[p+1] to an n^{th} output signal OUT[n]) according to a driving frequency of cHz in the third area DA3 (p+1^{th} to n^{th} rows). For example, the driving circuit DRV may sequentially output the output signal OUT 10 times per second in the first area DA1, may sequentially output the output signal OUT 120 times per second in the second area DA2, and may sequentially output the output signal OUT 30 times per second in the third area DA3.

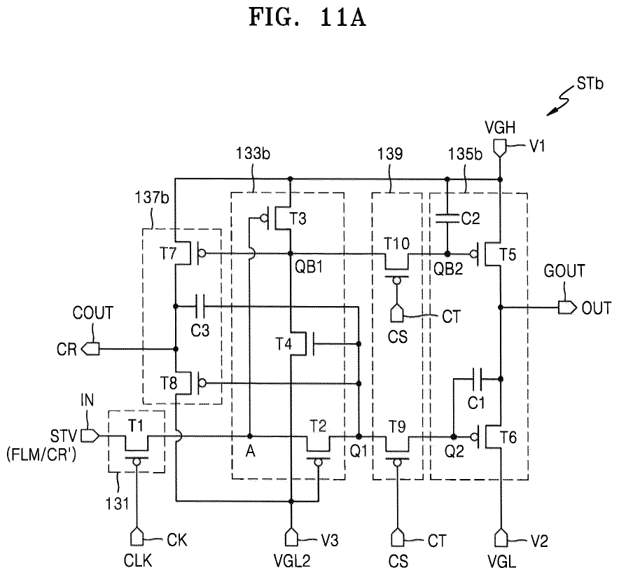

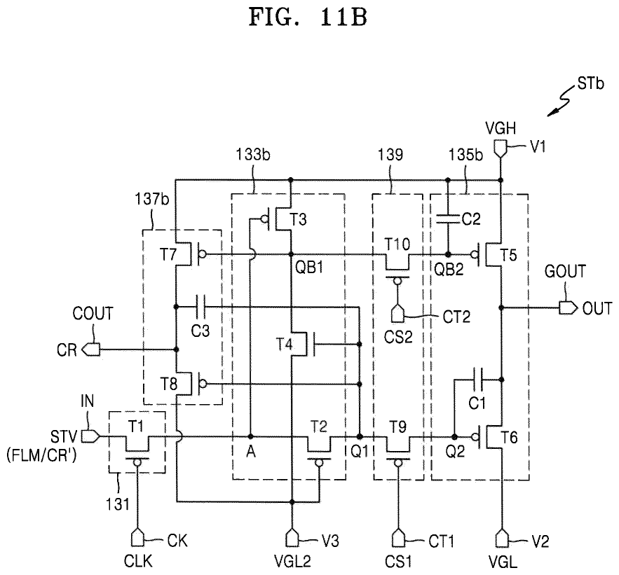

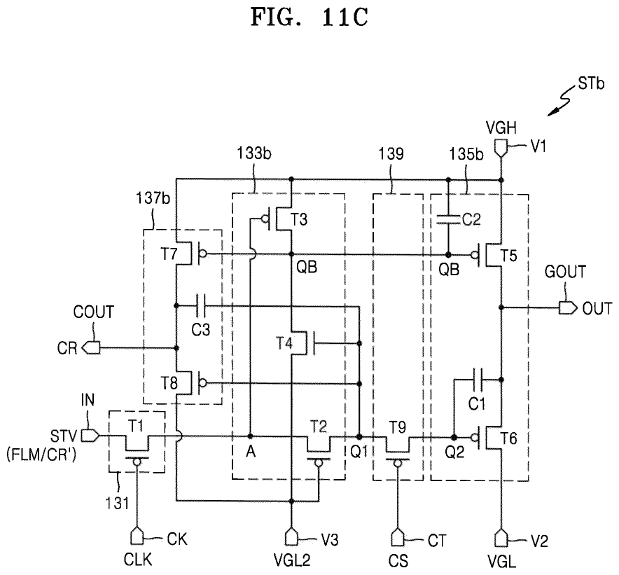

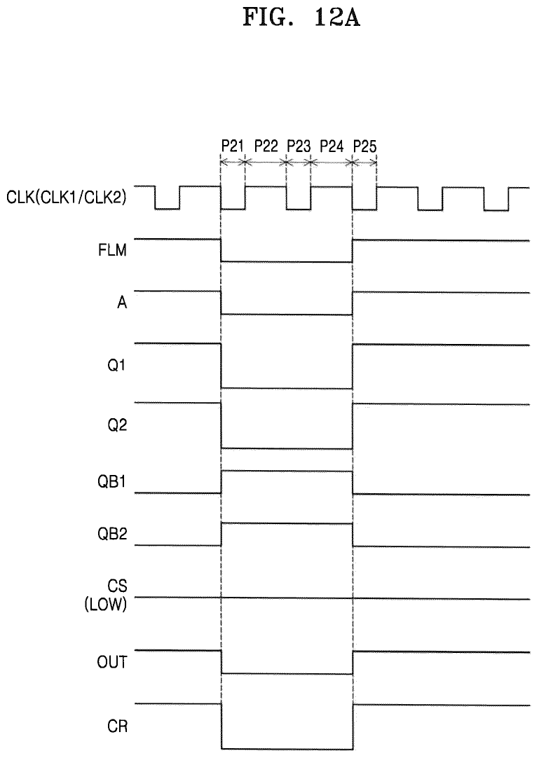

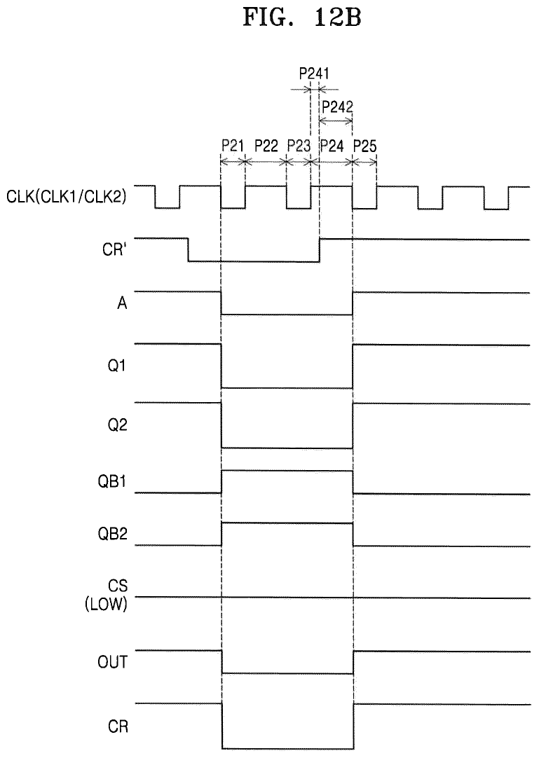

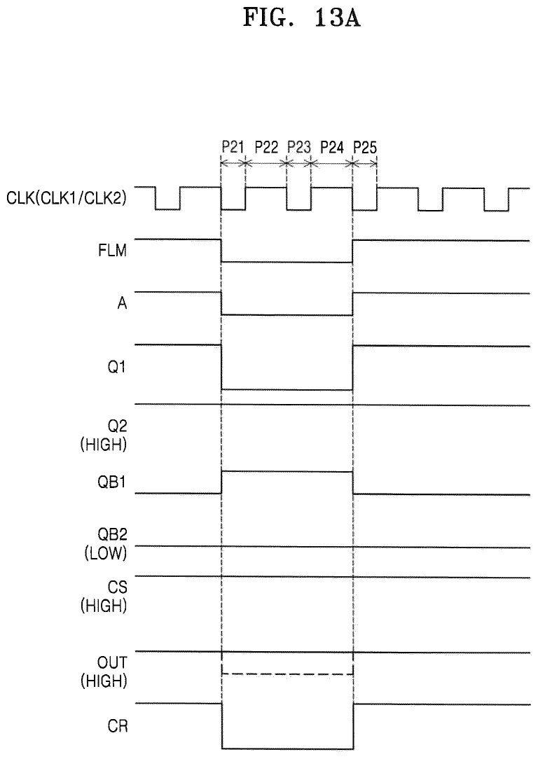

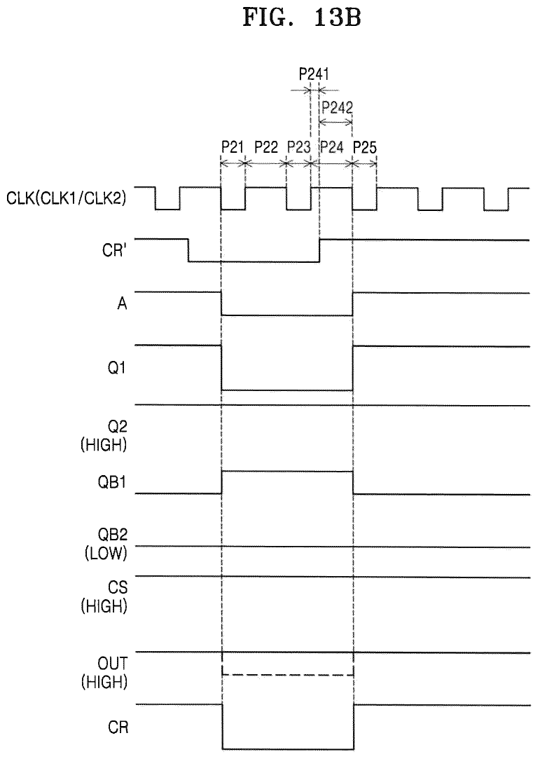

FIG. 10 is a diagram schematically illustrating a driving circuit, according to an embodiment. FIG. 11A to 11C are diagrams illustrating any one of a plurality of stages included in the driving circuit of FIG. 10. FIGS. 12A to 13B are timing diagrams for describing an operation of the stage of FIGS. 11A to 11C. Hereinafter, the same description as that made with reference to FIGS. 3 to 7 may be omitted.

Referring to FIG. 10, the stages (e.g., ST1 to STn) of the driving circuit DRV according to an embodiment may sequentially output output signals (e.g., OUT[1], OUT[2], OUT[3], OUT[4], . . . , and OUT[n]) to signal lines.

Each of the stages (e.g., ST1 to STn) may include a plurality of terminals to receive (input) and transmit (output) which a plurality of signals are input and output. The plurality of terminals may include the input terminal IN, the first voltage input terminal V1, the second voltage input terminal V2, the third voltage input terminal V3, a control terminal CT, the clock terminal CK, the first output terminal GOUT, and the second output terminal COUT.

The start signal STV may be input (supplied) to the input terminal IN. The external start signal FLM may be input as the start signal STV to the input terminal IN of the first stage ST1, and the previous carry signal CR′ (see FIG. 11A) may be input as the start signal STV to the input terminal IN of each of the second to n^{th} stages ST2 to STn.

The first voltage VGH may be input to the first voltage input terminal V1, the second voltage VGL may be input to the second voltage input terminal V2, and the third voltage VGL2 may be input to the third voltage input terminal V3.

A selection control signal CS may be input to the control terminal CT. The selection control signal CS may be a high-level signal HIGH or a low-level signal LOW corresponding to an output timing of the output signal OUT of each area of the display area DA. The selection control signal CS may be input from the controller 190 or the power supply circuit 170.

The clock signal CLK may be input to the clock terminal CK. The first clock signal CLK1 or the second clock signal CLK2 may be input to the clock terminal CK. As shown in FIG. 4, the first clock signal CLK1 and the second clock signal CLK2 may be signals in which a high-level voltage and a low-level voltage are periodically repeated.

The output signal OUT may be output from the first output terminal GOUT.

The carry signal CR may be output from the second output terminal COUT. A swing width between a high-level voltage and a low-level voltage of the carry signal CR may be greater than a swing width between a high-level voltage and a low-level voltage of the output signal OUT.

FIG. 11A illustrates an arbitrary stage STb among the stages (e.g., ST1 to STn). The stage STb may be an odd-numbered stage or an even-numbered stage. The start signal STV (e.g., the external start signal FLM or the previous carry signal CR′) may be input to the input terminal IN of the stage STb. The clock signal CLK (e.g., the first clock signal CLK1 or the second clock signal CLK2) may be input to the clock terminal CK of the stage STb.

The stage STb may include a logic circuit and an output circuit. As shown in FIG. 11A, the logic circuit may include the input circuit 131, a control circuit 133b, and a selection circuit 139, and the output circuit may include a first output circuit 135b and a second output circuit 137b. Each of the input circuit 131, the control circuit 133b, the selection circuit 139, the first output circuit 135b, and the second output circuit 137b may include at least one transistor. The at least one transistor may include an N-channel transistor and/or a P-channel transistor. For example, a fourth transistor T4 may be an N-channel transistor, and a first transistor T1, a second transistor T2, a third transistor T3, a fifth transistor T5, a sixth transistor T6, a seventh transistor T7, an eighth transistor T8, a ninth transistor T9, and a tenth transistor T10 may be P-channel transistors.

The input circuit 131 may transmit the start signal STV to the first node A in response to the clock signal CLK input to the clock terminal CK. The input circuit 131 may include the first transistor T1.

The first transistor T1 may be connected between the input terminal IN and the first node A. A gate of the first transistor T1 may be connected to the clock terminal CK. The first transistor T1 may be turned on when the clock signal CLK input to the clock terminal CK is at a low level, allowing the start signal STV input to the input terminal IN to be transmitted to the first node A. In an embodiment, when the start signal STV is a low-level voltage, a voltage of the first node A may be higher than a low-level voltage of the start signal STV due to threshold voltage loss of the first transistor T1.

The control circuit 133b may control voltages of the second node Q1 and the third node QB1 according to a voltage of the first node A. For example, the control circuit 133b may control voltages of the second node Q1 and the third node QB1 according to a voltage of a signal transmitted to the first node A through the first transistor T1. The control circuit 133b may include the second to fourth transistors T2 to T4.

The second transistor T2 may be connected between the first node A and the second node Q1. A gate of the second transistor T2 may be connected to the third voltage input terminal V3. The second transistor T2 may be turned on by the third voltage VGL2 input to the third voltage input terminal V3, allowing the start signal STV passed through the first transistor T1 to be transmitted to the second node Q1.

The third transistor T3 may be connected between the first voltage input terminal V1 and the third node QB1. In an embodiment, as shown in FIGS. 11A to 11C, a gate of the third transistor T3 may be connected to the first node A. In an embodiment, the gate of the third transistor T3 may be connected to the second node Q1. The third transistor T3 may be turned on when a voltage of the first node A is at a low level, allowing the first voltage VGH input to the first voltage input terminal V1 to be transmitted to the third node QB1. Due to the third transistor T3, a voltage of the third node QB1 may be a voltage of a voltage level obtained by inverting a voltage level of the first node A.

The fourth transistor T4 may be connected between the third node QB1 and the third voltage input terminal V3. A gate of the fourth transistor T4 may be connected to the second node Q1. The fourth transistor T4 may be turned on when a voltage of the second node Q1 is at a high level, allowing the third voltage VGL2 input to the third voltage input terminal V3 to be transmitted to the third node QB1. Due to the fourth transistor T4, a voltage of the third node QB1 may be a voltage of a voltage level obtained by inverting a voltage level of the second node Q1.

The third transistor T3 and the fourth transistor T4 may control a voltage level of the third node QB1 according to a voltage level of the first node A, and thus, may function as inverters or level shifters.

The first output circuit 135b may be connected between the first voltage input terminal V1 and the second voltage input terminal V2. The first output circuit 135b may output the output signal OUT of a high-level voltage or a low-level voltage according to voltages of a fourth node Q2 and a fifth node QB2. The first output circuit 135b may include the fifth transistor T5 and the sixth transistor T6. The first output circuit 135b may further include the first capacitor C1 and the second capacitor C2.

The fifth transistor T5 may be connected between the first voltage input terminal V1 and the first output terminal GOUT. A gate of the fifth transistor T5 may be connected to the fifth node QB2. The fifth transistor T5 may be a pull-up transistor that transmits a high-level voltage to the first output terminal GOUT. The fifth transistor T5 may be turned on when a voltage of the fifth node QB2 is at a low level, allowing the first voltage VGH of a high level input to the first voltage input terminal V1 to be transmitted to the first output terminal GOUT.

The sixth transistor T6 may be connected between the first output terminal GOUT and the second voltage input terminal V2. A gate of the sixth transistor T6 may be connected to the fourth node Q2. The sixth transistor T6 may be a pull-down transistor that transmits a low-level voltage to the first output terminal GOUT. The sixth transistor T6 may be turned on when a voltage of the fourth node Q2 is at a low level, allowing the second voltage VGL of a low level input to the second voltage input terminal V2 to be transmitted to the first output terminal GOUT.

The first capacitor C1 may be connected between the first output terminal GOUT and the fourth node Q2. The second capacitor C2 may be connected between the first voltage input terminal V1 and the fifth node QB2. The first capacitor C1 may maintain a voltage of the fourth node Q2, and the second capacitor C2 may maintain a voltage of the fifth node QB2. In an embodiment, when capacitance by the first output terminal GOUT and the fourth node Q2 is sufficiently large, the first capacitor C1 may be omitted.

The second output circuit 137b may be connected between the first voltage input terminal V1 and the third voltage input terminal V3. The second output circuit 137b may output the carry signal CR of a high-level voltage or a low-level voltage according to a voltage of the third node QB1 and the second node Q1. The second output circuit 137b may include the seventh transistor T7 and the eighth transistor T8. The second output circuit 137b may further include a third capacitor C3. In an embodiment, channel types of the third transistor T7 and the fourth transistor T8 are the same.

The seventh transistor T7 may be connected between the first voltage input terminal V1 and the second output terminal COUT. A gate of the seventh transistor T7 may be connected to the third node QB1. The seventh transistor T7 may be a pull-up transistor that transmits a high-level voltage to the second output terminal COUT. The seventh transistor T7 may be turned on when a voltage of the third node QB1 is at a low level, allowing the first voltage VGH of a high level input to the first voltage input terminal V1 to be transmitted to the second output terminal COUT.

The eighth transistor T8 may be connected between the second output terminal COUT and the third voltage input terminal V3. A gate of the eighth transistor T8 may be connected to the second node Q1. The eighth transistor T8 may be a pull-down transistor that transmits a low-level voltage to the second output terminal COUT. The eighth transistor T8 may be turned on when the voltage of the second node Q1 is at a low level, allowing the third voltage VGL2 of a low level input to the third voltage input terminal V3 to be transmitted to the second output terminal COUT.

The third capacitor C3 may be connected between the second output terminal COUT and the second node Q1. The third capacitor C3 may change a voltage of the second node Q1 in accordance with a voltage change of the second output terminal COUT.

The selection circuit 139 may control the output of the output signal OUT from the first output circuit 135b in response to the selection control signal CS. The selection circuit 139 may be located between the control circuit 133b and the first output circuit 135b. When the selection control signal CS is at a high level, the selection circuit 139 may block an electrical connection between the second node Q1 and/or the third node QB1 and the first output circuit 135b. The selection circuit 139 may include the ninth transistor T9 and the tenth transistor T10. For example, the selection circuit 139 may control whether the output signal OUT is transmitted from the first output circuit 135b based on the selection control signal CS.

The ninth transistor T9 (first selection transistor) may be connected between the second node Q1 and the fourth node Q2. A gate of the ninth transistor T9 may be connected to the control terminal CT. When the selection control signal CS is at a low level, the ninth transistor T9 may be turned on to electrically connect the second node Q1 to the fourth node Q2. When the selection control signal CS is at a high level, the ninth transistor T9 may be turned off to electrically block the second node Q1 and the fourth node Q2. For example, when the selection control signal CS is at the high level, the ninth transistor T9 may be turned off, thereby electrically isolating the second node Q1 and the fourth node Q2.

The tenth transistor T10 (the second selection transistor) may be connected between the third node QB1 and the fifth node QB2. A gate of the tenth transistor T10 may be connected to the control terminal CT. When the selection control signal CS is at a low level, the tenth transistor T10 may be turned on to electrically connect the third node QB1 to the fifth node QB2. When the selection control signal CS is at a high level, the tenth transistor T10 may be turned off to electrically block the third node QB1 and the fifth node QB2. For example, when the selection control signal CS is at a high level, the tenth transistor T10 may be turned off, electrically isolating the third node QB1 from the fifth node QB2.

In a state where the ninth transistor T9 and the tenth transistor T10 are turned off, a voltage of the fourth node Q2 may be maintained by the first capacitor C1, and a voltage of the fifth node QB2 may be maintained by the second capacitor C2.

Although the ninth transistor T9 and the tenth transistor T10 receive the selection control signal CS in FIG. 11A, embodiments are not limited thereto. For example, in an embodiment, as shown in FIG. 11B, a control terminal CT1 to which the gate of the ninth transistor T9 is connected and a control terminal CT2 to which the gate of the tenth transistor T10 is connected may be separated from each other. The control terminal CT1 to which the gate of the ninth transistor T9 is connected may receive a first selection control signal CS1, and the control terminal CT2 to which the gate of the tenth transistor T10 is connected may receive a second selection control signal CS2. In an embodiment, as shown in FIG. 11C, the tenth transistor T10 may be omitted, and the third node QB1 and the fifth node QB2 may be electrically connected nodes QB. For example, when the tenth transistor T10 is omitted, the third node QB1 and the fifth node QB2 may be electrically connected as a common node.

An operation of the stage STb of FIG. 11A will be described with reference to FIGS. 12A to 13B. FIGS. 12A and 12B are timing diagrams for describing an operation in which the stage of FIG. 11A outputs an output signal. FIGS. 13A and 13B are timing diagrams for describing an operation in which the stage of FIG. 11A does not output an output signal. When an output signal is output, it may mean that a low-level output signal is output, and when an output signal is not output, it may mean that a high-level output signal is output.

FIGS. 12A and 13A are timing diagrams for describing an operation of the stage of FIG. 11A when a start signal is the external start signal FLM. FIGS. 12B and 13B are timing diagrams for describing an operation of the stage of FIG. 11A when a start signal is the previous carry signal CR′.

In FIGS. 12A to 13B, the external start signal FLM or the previous carry signal CR′ as the start signal STV input to the input terminal IN, the first clock signal CLK1 or the second clock signal CLK2 as the clock signal CLK input to the clock terminal CK, voltages of the first to fifth nodes A, Q1, QB1, Q2, and QB2, the selection control signal CS, the output signal OUT, and the carry signal CR are illustrated.

A low-level voltage of the clock signal CLK may be the second voltage VGL, and a high-level voltage of the clock signal CLK may be the first voltage VGH. A low-level voltage of the external start signal FLM may be the third voltage VGL2, and a high-level voltage of the external start signal FLM may be the first voltage VGH. A low-level voltage of the carry signal CR and the previous carry signal CR′ may be the third voltage VGL2, and a high-level voltage the carry signal CR and the previous carry signal CR′ may be the first voltage VGH. A low-level voltage of the output signal OUT may be the second voltage VGL, and a high-level voltage of the output signal OUT may be the first voltage VGH.

An operation in which the stage of FIG. 11A outputs an output signal will be described with reference to FIGS. 12A and 12B. The selection control signal CS of a low level may be input to the control terminal CT of the stage STb. In an embodiment, the selection control signal CS of a low level is a voltage lower than the second voltage VGL.

In a first interval P21, the clock signal CLK of a low level may be input to the clock terminal CK, and the start signal STV (e.g., the external start signal FLM of FIG. 12A or the previous carry signal CR′ of FIG. 12B) may be input to the input terminal IN.

The first transistor T1 may be turned on by the clock signal CLK of a low level, and the start signal STV of a low level may be transmitted to the first node A by the first transistor T1 that is turned on. In an embodiment, a voltage of the first node A may be a third voltage, which is a low-level voltage of the start signal STV. In an embodiment, a voltage of the first node A is higher than the third voltage VGL2, which is a low-level voltage of the start signal STV, by a magnitude (absolute value) of a threshold voltage Vth_t1 of the first transistor T1 due to threshold voltage loss of the first transistor T1.

The second transistor T2 may be turned on by the third voltage VGL2 of a low level, which is a gate voltage of the second transistor T2, and a signal of the first node A may be transmitted to the second node Q1 by the second transistor T2 that is turned on. A voltage of the second node Q1 may drop to a level of the first node A, causing the second transistor T2 to function as a reverse-biased diode.

The eighth transistor T8 with its gate connected to the second node Q1 may be turned on, allowing the third voltage VGL2 of a low level to be transmitted to the second output terminal COUT through the turned-on eighth transistor T8. Accordingly, the carry signal CR may be output as the third voltage VGL2 of a low level. In this case, as a voltage of the second output terminal COUT transitions from a high level to a low level, the low-level voltage of the second node Q1 may be further reduced (e.g., downwardly boosted) due to capacitive coupling with the third capacitor C3, and may drop additionally by a voltage change amount (ΔV=first voltage VGH-third voltage VGL2) corresponding to the change at the second output terminal COUT. In an embodiment, after the downward boosting, a voltage of the second node Q1 may be approximately the third voltage VGL2.

The third transistor T3 with its gate connected to the first node A may be turned on, allowing the fourth transistor T4 with its gate connected to the second node Q1 to be turned off. The first voltage VGH of a high level may be transmitted to the third node QB1 through the turned-on third transistor T3, allowing a voltage of the third node QB1 to be the first voltage VGH of a high level. The seventh transistor T7 with the gate connected to the third node QB1 may be turned off.

Because the ninth transistor T9 and the tenth transistor T10 are turned on by the selection control signal CS of a low level, a voltage of the fourth node Q2 may be a voltage of the second node Q1, and a voltage of the fifth node QB2 may be a voltage of the third node QB1.

The sixth transistor T6 with its gate connected to the fourth node Q2 may be turned on, while the fifth transistor T5 with its gate connected to the fifth node QB2 may be turned off. The second voltage VGL of a low level may be transmitted to the first output terminal GOUT through the turned-on sixth transistor T6. Accordingly, the output signal OUT may be the second voltage VGL of a low level.

In a second interval P22, the clock signal CLK of a high level may be input to the clock terminal CK, and the start signal STV of a low level may be input to the input terminal IN.

The first transistor T1 may be turned off by the clock signal CLK of a high level, and a voltage of the first node A may maintain a low-level voltage of the first interval P21. A voltage of the second node Q1 and a voltage of the fourth node Q2 may maintain a low-level voltage of the first interval P21 due to the second transistor T2 and the ninth transistor T9 that are turned on.

A voltage of the third node QB1 and a voltage of the fifth node QB2 may maintain a high-level voltage of the first interval P21 due to the third transistor T3 and the tenth transistor T10 that are turned on.

Accordingly, the output signal OUT from the first output terminal GOUT may be continuously output (or continue to be maintained) at a low level, and the carry signal CR from the second output terminal COUT may be continuously output at a low level.

In a third interval P23, the start signal STV of a low level may be input to the input terminal IN, and the clock signal CLK of a low level may be input to the clock terminal CK.

Although the first transistor T1 is turned on by the clock signal CLK of a low level, because the start signal STV is at a low level, a voltage of each of the first node A, the second node Q1, the third node QB1, the fourth node Q2, and the fifth node QB2 may maintain a voltage of a previous interval (e.g., the second interval P22).

Accordingly, the output signal OUT from the first output terminal GOUT may be continuously output (or continue to be maintained) at a low level, and the carry signal CR from the second output terminal COUT may be continuously output at a low level.

When the start signal STV is the external start signal FLM, in a fourth interval P24, the external start signal FLM of a low level may be input to the input terminal IN, and the clock signal CLK of a high level may be input to the clock terminal CK. When the start signal STV is the previous carry signal CR', in the fourth interval P24, the clock signal CLK of a high level may be input to the clock terminal CK; in a 4-1 interval P241 of the fourth interval P24, the previous carry signal CR′ of a low level may be input to the input terminal IN; and in a 4-2 interval P242 of the fourth interval P24, the previous carry signal CR′ of a high level may be input to the input terminal IN.

Because the first transistor T1 is turned off by the clock signal CLK of a high level, the voltages at the first node A, the second node Q1, the third node QB1, the fourth node Q2, and the fifth node QB2 may remain at the levels held during a previous interval (e.g., the third interval P23), regardless of the voltage level of the start signal STV.

Accordingly, the output signal OUT from the first output terminal GOUT may be continuously output at a low level, and the carry signal CR from the second output terminal COUT may be continuously output at a low level.

In a fifth interval P25, the clock signal CLK of a low level may be input to the clock terminal CK, and the start signal STV of a high level may be input to the input terminal IN.

The first transistor T1 may be turned on by the clock signal CLK of a low level, allowing the start signal STV of a high level to be transmitted to the first node A through the turned-on first transistor T1. A voltage of the first node A1 may be the first voltage VGH, which is a high-level voltage of the start signal STV. A voltage of the second node Q1 may be a voltage of the first node A due to the second transistor T2 that is turned on by the third voltage VGL2 of a low level.

The third transistor T3 with its gate connected to the first node A may be turned off, and the fourth transistor T4 with its gate connected to the second node Q1 may be turned on. The third voltage VGL2 of a low level may be transmitted to the third node QB1 through the turned-on fourth transistor T4, and a voltage of the third node QB1 may be the third voltage VGL2 of a low level. The seventh transistor T7 with its gate connected to the third node QB1 may be turned on. The first voltage VGH of a high level may be transmitted to the second output terminal COUT through the turned-on seventh transistor T7. Accordingly, the carry signal CR may be the first voltage VGH of a high level.

Because the ninth transistor T9 and the tenth transistor T10 are turned on by the selection control signal CS of a low level, a voltage of the fourth node Q2 may be a voltage of the second node Q1 and a voltage of the fifth node QB2 may be a voltage of the third node QB1. The sixth transistor T6 with its gate connected to the fourth node Q2 may be turned off, and the fifth transistor T5 with its gate connected to the fifth node QB2 may be turned on. The first voltage VGH of a high level may be transmitted to the first output terminal GOUT through the turned-on fifth transistor T5. Accordingly, the output signal OUT may be the first voltage VGH of a high level.

An operation in which the stage of FIG. 11A does not output an output signal will be described with reference to FIGS. 13A and 13B. The selection control signal CS of a high level may be input to the control terminal CT of the stage STb.

In the first interval P21 to the fifth interval P25, operations of the input circuot 131, the control circuit 133b, and the second output circuit 137b are the same as those when outputting a carry signal described with reference to FIGS. 12A and 12B.

In the first interval P21 to the fifth interval P25, because the ninth transistor T9 and the tenth transistor T10 are turned off by the selection control signal CS of a high level, the fourth node Q2 and the fifth node QB2 may be floated. A voltage of the fourth node Q2 may remain at a high-level voltage, corresponding to a node voltage before the first interval P21, due to the first capacitor C1, while a voltage of the fifth node QB2 may remain at a low-level voltage, corresponding to a node voltage before the first interval P21, due to the second capacitor C2.

The sixth transistor T6 with its gate connected to the fourth node Q2 may maintain a turn-off state, and the fifth transistor T5 with its gate connected to the fifth node QB2 may maintain a turn-on state. The first voltage VGH of a high level may be transmitted to the first output terminal GOUT through the turned-on fifth transistor T5, and the output signal OUT may be the first voltage VGH of a high level.

Operations of the stages STb of FIGS. 11B and 11C are the same as or similar to an operation of the stage STb of FIG. 11A described with reference to the timing diagrams of FIGS. 12A to 13B. In the operation of the stage STb of FIG. 11B, phases of the first selection control signal CS1 and the second selection control signal CS2 may be same. In the stage STb of FIG. 11C, in the first interval P21 to the fourth interval P24, because the fourth node Q2 is floated by the ninth transistor T9 and the node QB is a high-level voltage, the fifth transistor T5 and the sixth transistor T6 may be turned off, and the output signal OUT may be the first voltage VGH of a high level before the first interval P21.

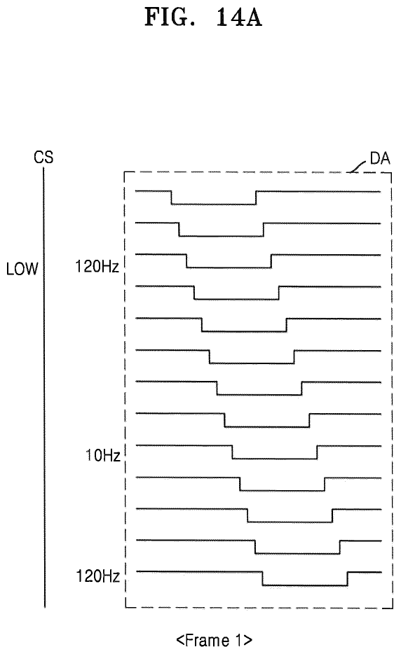

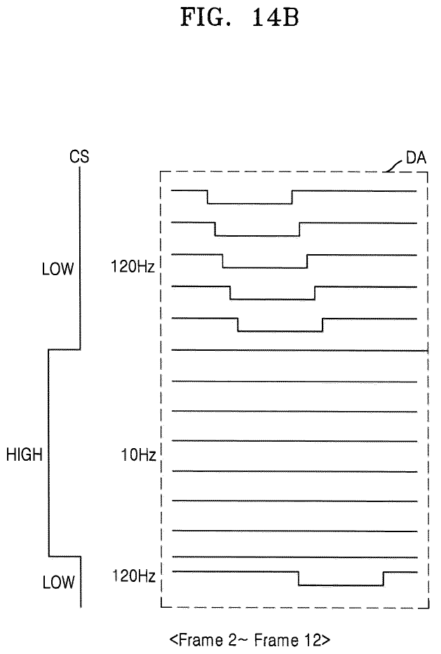

FIGS. 14A and 14B are diagrams illustrating the selection control signal CS and an output of a driving circuit for each frame in a second driving mode, according to an embodiment.

In the second driving mode M-MODE, the driving circuit DRV may control the output of the output signal OUT for each area according to a driving frequency for each area. For example, the driving circuit DRV may output an output signal 120 times per second in a 120 Hz driving area (high-frequency area), and may output an output signal 10 times per second in a 10 Hz driving area (low-frequency area).

Referring to FIG. 14A, in a first frame Frame 1, a plurality of stages may sequentially output output signals in a high-frequency area and a low-frequency area. During the first frame Frame 1, the selection control signal CS may be input as a low-level voltage LOW to the driving circuit DRV.

Referring to FIG. 14B, from a second frame Frame 2 to a 12^{th} frame Frame 12, in each frame, a plurality of stages may sequentially output output signals in a high-frequency area and do not output output signals in a low-frequency area. While the output signals are sequentially output in the high-frequency area, the selection control signal CS may be input as the low-level voltage LOW to the driving circuit DRV, and while the output signals are not output in the low-frequency area, the selection control signal CS may be input as a high-level voltage HIGH to the driving circuit DRV.

From a 13^{th} frame to a 120^{th} frame, the driving circuit DRV may output output signals in units of 12 frames as shown in FIGS. 14A and 14B.

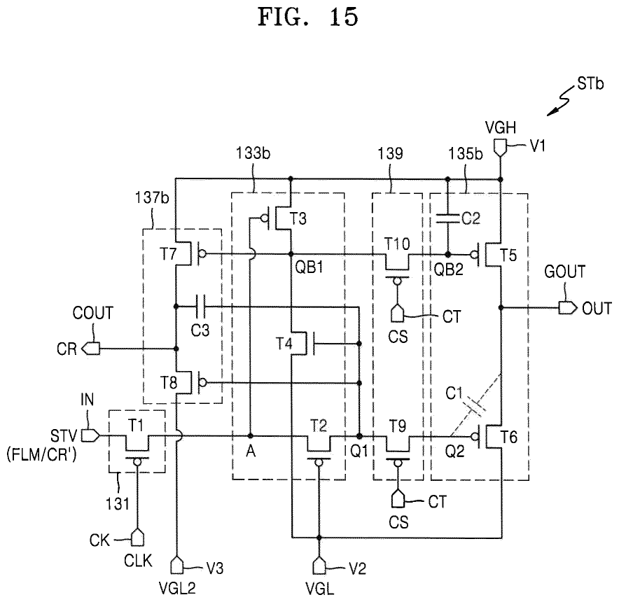

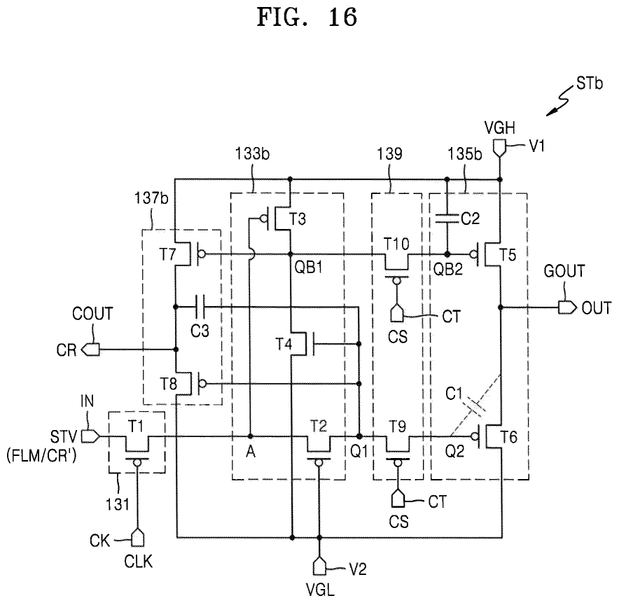

FIGS. 15 and 16 are diagrams illustrating any one of a plurality of stages included in the driving circuit of FIG. 10, according to an embodiment. The stage STb of each of FIG. 15 and FIG. 16 is the same as the stage STb of FIG. 11A except that a voltage input terminal to which the second transistor T2 and the eighth transistor T8 are connected in FIG. 15 is different from a voltage input terminal to which the second transistor T2 and the eighth transistor T8 are connected in FIG. 11A.

Referring to FIG. 15, in an embodiment, the gate of the second transistor T2 may be connected to the second voltage input terminal V2, and the gate of the second transistor T2 may receive the second voltage VGL.

Referring to FIG. 16, in an embodiment, the gate of the second transistor T2 and one terminal of the eighth transistor T8 may be connected to the second voltage input terminal V2. When the second node Q1 is at a low level, the eighth transistor T8 may be turned on, and may output the second voltage VGL input to the second voltage input terminal V2 as a low-level voltage of the carry signal CR.

The embodiments of FIGS. 15 and 16 may be modified, like the embodiment of FIGS. 11B and 11C.

A display device according to an embodiment may display an image at a different driving frequency for each area of a display area, and a selection circuit for controlling an output of a gate driver may be provided in each stage so that some gate signals are not supplied to pixels according to a driving frequency for each area. The selection circuit may control an output of a gate output circuit by including the first selection transistor T9 for controlling electrical connection between the second node Q1 and the fourth node (the gate node) Q2 of a pull-down transistor of the gate output circuit and the second selection transistor T10 for controlling electrical connection between the third node QB1 and the fifth node (the gate node) QB2 of a pull-up transistor of the gate output circuit. For example, the display area may be divided into three regions: top, middle, and bottom. The top region may be driven at 120 Hz for dynamic content, the middle region at 60 Hz for standard content, and the bottom region at 30 Hz for mostly static images. In each stage of the gate driver corresponding to these areas, the selection circuit determines whether to output a gate signal based on the assigned frequency. In the top region, the selection transistors remain turned on in every frame, allowing gate signals to be supplied consistently. In the middle region, the selection transistors may be turned on every other frame, skipping gate signal output intermittently. In the bottom region, the selection transistors may be turned on only once every four frames, blocking gate signal output in the remaining frames. This selective gate signal suppression, controlled by the first and second selection transistors in each stage, helps reduce power consumption without affecting visual quality in low-refresh regions.

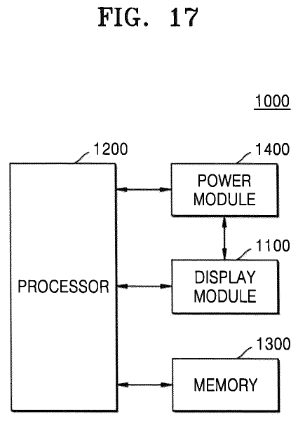

FIG. 17 is a block diagram illustrating an electronic device, according to an embodiment.

Referring to FIG. 17, an electronic device 1000 according to an embodiment may include a display module 1100, a processor 1200, a memory 1300, and a power module 1400.

The electronic device 1000 may output various information through the display module 1100 within an operating system.

The processor 1200 may include at least one of a central processing unit (CPU), an application processor (AP), a graphics processing unit (GPU), a communication processor (CP), an image signal processor (ISP), and a controller. In an embodiment, the processor 1200 may be divided into two or more from a functional or structural point of view. For example, the processor 1200 may include a main processor as a first driving chip including a CPU, and an auxiliary processor as a second driving chip including a controller that receives an image signal from the main processor and processes the image signal to meet interface specifications of the display module 1100.

The memory 1300 may include at least one of a volatile memory and a non-volatile memory. The memory 1300 may store data information necessary for an operation of the processor 1200 or the display module 1100. When the processor 1200 executes an application stored in the memory 1300, an image data signal and/or an input control signal may be transmitted to the display module 1100, and the display module 1100 may process the received signal and may output image information through a display screen.

The power module 1400 may include a power supply module, such as a power adaptor or a battery device, and a power conversion module configured to convert power supplied by the power supply module and generate power necessary for an operation of the electronic device 1000. Power conversion by the power conversion module may include, but is not limited to, direct current (DC)-DC conversion, alternating current (AC)-DC conversion, and DC-AC conversion.

At least one of the components of the electronic device 1000 described above may be included in the display device according to the embodiments described above. Also, some of individual modules functionally included in one module may be included in the display device and the others may be provided separately from the display device. For example, the display device may include the display module 1100 and the auxiliary processor among the processor 120, and the main process among the processor 1200, the memory 1300, and the power module 1400 may be provided as other devices in the electronic device 1000, rather than the display device. In another example, the power module 1400 may be provided in the display device, and may supply power to the processor 1200 and the memory 1300 provided in the electronic device 1000, rather than the display device. However, the disclosure is not limited thereto.

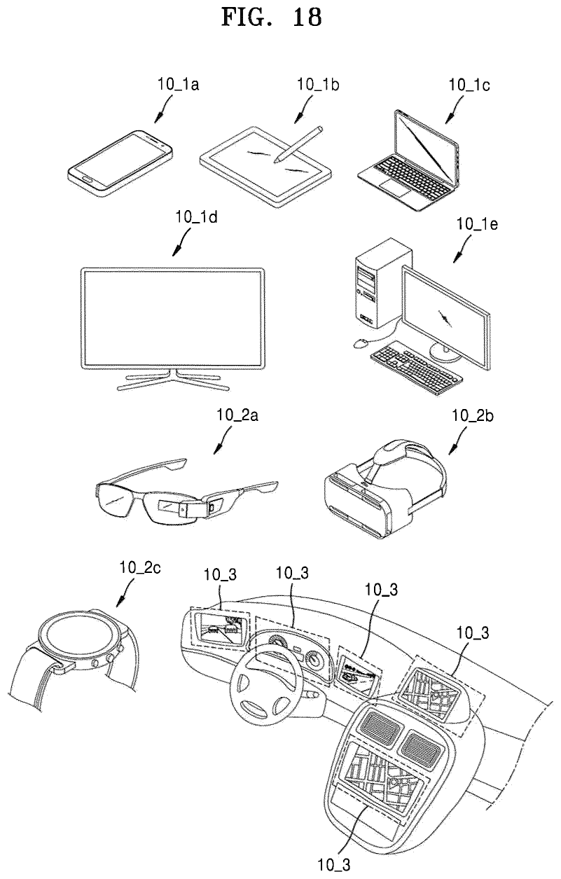

### FIG. 18 is a schematic view illustrating electronic devices, according to various embodiments.

A display device according to embodiments is a device for displaying a moving image or a still image and may be applied to various electronic devices. Referring to FIG. 18, various electronic devices to which the display device according to embodiments is applied may include not only electronic devices for displaying an image such as a smartphone 10_1a, a tablet PC 10_1b, a laptop 10_1c, a TV 10_1d, and a desk monitor 10_1e, but also wearable electronic devices including a display module such as smart glasses 10_2a, a head-mounted display 10_2b, and a smart watch 10_2c, and electronic devices for a vehicle 10_3 including a display module such as a center information display (CID) disposed on an instrument panel, a center fascia, or a dash board of a vehicle, and a room mirror display. The electronic device 1000 according to embodiments is not limited to the above devices.

The electronic device of FIG. 18 may include components illustrated in FIG. 17. For example, the smartphone 10_1a may include the display module 1100, the processor 1200, the memory 1300, and the power module 1400 of FIG. 17. The smartphone 10_1a may further include a communication module and a battery device. Power provided by the battery device may be converted through the power module 1400 and may be provided to the processor 1200, the memory 1300, and the display module 1100. In an embodiment, the display device applied to the smartphone 10_1a may include the display module 1100, and may further include the power module 1400. The processor 1200 and the memory 1300 may be provided as chips mounted on a mother board, which is an external device, but the disclosure is not limited thereto.

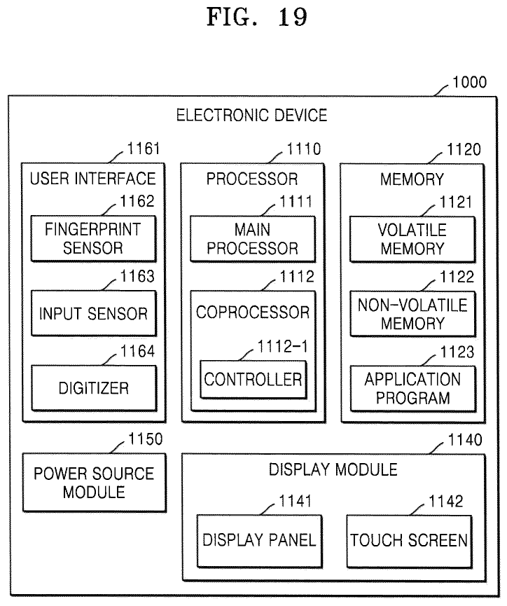

FIG. 19 is a diagram illustrating an electronic device according to an embodiment of the present invention. Referring to FIG. 19, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141. For example, the display module 1140 may be used to implement the display module 1100 shown in FIG. 17. For example, the memory 1120 may be used to implement the memory 1300 shown in FIG. 17. For example, the processor 1110 may be used to implement the processor 1200 shown in FIG. 17.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area for interaction and a non-display area including sensors and circuits for enhanced functionality. For example, the electronic device 1000 may be a television or monitor including a large display area for high-resolution video playback and a non-display area incorporating driving circuits or connectivity modules for external inputs. For example, the electronic device 1000 may be a smartwatch including a display area optimized for compact and high-clarity visuals and a non-display area integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications of the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. For example, the touch screen 1142 may be included within the input/output device. The display module 1140 may further include a window, a chassis, and a bracket to protect the display panel 1141. The display module 1140 may include at least a part of the configuration of the display device 10 shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164. For example, the fingerprint sensor 1162, the input sensor 1163, and a digitizer 1164 may be included within the input/output device.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared detector or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display panel 110 shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140. For example, the power source module 1150 may be used to implement the power module 1400.

According to an embodiment, there may be provided a driving circuit capable of outputting a gate signal with low power and stably and a display device including the driving circuit. However, the effects of the disclosure are not limited to the above effects, and may vary without departing from the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A driving circuit comprising a plurality of stages, wherein each of the plurality of stages comprise:
an input circuit configured to transmit a start signal to a first node;
a first output circuit connected to a first terminal receiving a first voltage and a second terminal receiving a second voltage, the first output circuit being configured to output an output signal to a signal line;
a second output circuit connected to the first terminal and a third terminal receiving a third voltage, the second output circuit being configured to output a carry signal to a next stage; and
a control circuit configured to control voltages of nodes to which the first output circuit and the second output circuit are connected according to a voltage of the first node,
wherein a high-level voltage of the output signal is the first voltage, and a low-level voltage of the output signal is the second voltage that is lower than the first voltage, and
a high-level voltage of the carry signal is the first voltage, and a low-level voltage of the carry signal is the third voltage that is lower than the second voltage.

2. The driving circuit of claim 1, wherein the input circuit comprises a first transistor connected to the first node and to an input terminal receiving the start signal, and comprising a gate connected to a clock terminal receiving a clock signal.

3. The driving circuit of claim 2, wherein the control circuit comprises:
a second transistor connected to the first node and a second node, and comprising a gate connected to the third terminal;
a third transistor connected to the first terminal and a third node, and comprising a gate connected to the first node; and
a fourth transistor connected to the third node and the third terminal, and comprising a gate connected to the second node.

4. The driving circuit of claim 3, wherein channel types of the third transistor and the fourth transistor are different from each other.

5. The driving circuit of claim 2, wherein the first output circuit comprises:
a fifth transistor connected to the first terminal and a first output terminal, and comprising a gate connected to a third node; and
a sixth transistor connected to the first output terminal and the second terminal, and comprising a gate connected to a second node.

6. The driving circuit of claim 5, wherein the first output circuit further comprises:
a first capacitor connected to the first output terminal and the second node; and
a second capacitor connected to the first terminal and the third node.

7. The driving circuit of claim 2, wherein the second output circuit comprises:
a seventh transistor connected to the first terminal and a second output terminal, and comprising a gate connected to a third node; and
an eighth transistor connected to the second output terminal and the third terminal, and comprising a gate connected to the third node.

8. The driving circuit of claim 7, wherein channel types of the seventh transistor and the eighth transistor are different from each other.

9. The driving circuit of claim 2, wherein, when a low-level voltage of the start signal is transmitted to a second node to change the output signal from the first voltage to the second voltage, a voltage of the second node decreases by a difference between the first voltage and the second voltage, and the voltage of the second node is lower than the voltage of the first node.

10. The driving circuit of claim 2, further comprising a selection circuit connected between the control circuit and the first output circuit, wherein the selection circuit comprises:
a first selection transistor connected to a second node and a fourth node, and comprising a gate connected to a control terminal receiving a selection control signal; and
a second selection transistor connected to a third node and a fifth node, and comprising a gate connected to the control terminal.

11. The driving circuit of claim 10, wherein the control circuit comprises:
a second transistor connected to the first node and the second node, and comprising a gate connected to the third terminal;
a third transistor connected to the first terminal and the third node, and comprising a gate connected to the first node; and
a fourth transistor connected to the third node and the third terminal, and comprising a gate connected to the second node.

12. The driving circuit of claim 11, wherein channel types of the third transistor and the fourth transistor are different from each other.

13. The driving circuit of claim 10, wherein the first output circuit comprises:
a fifth transistor connected to the first terminal and a first output terminal, and comprising a gate connected to the fifth node; and
a sixth transistor connected to the first output terminal and the second terminal, and comprising a gate connected to the fourth node.

14. The driving circuit of claim 13, wherein the first output circuit further comprises:
a first capacitor connected to the first output terminal and the fourth node; and
a second capacitor connected to the first terminal and the fifth node.

15. The driving circuit of claim 10, wherein the second output circuit comprises:
a seventh transistor connected to the first terminal and a second output terminal, and comprising a gate connected to the third node; and
an eighth transistor connected to the second output terminal and the third terminal, and comprising a gate connected to the second node.

16. The driving circuit of claim 15, wherein, the second output circuit further comprises a third capacitor connected to the second output terminal and the second node.

17. The driving circuit of claim 10, wherein, when a low-level voltage of the start signal is transmitted to the second node to change the carry signal from the first voltage to the third voltage, a voltage of the second node decreases by a difference between the first voltage and the third voltage, and the voltage of the second node is lower than the voltage of the first node.

18. An electronic device comprising:
a controller configured to receive a multi-frequency driving flag signal from a processor and output a multi-frequency driving control signal based on the multi-frequency driving flag signal; and
a driving circuit comprising a plurality of stages configured to receive the multi-frequency driving control signal and output a gate signal at a different frequency for each area of a display area, wherein each of the plurality of stages comprises:
an input circuit configured to transmit a start signal to a first node;
a first output circuit connected to a first terminal receiving a first voltage and a second terminal receiving a second voltage, the first output circuit being configured to output an output signal to a signal line;
a second output circuit connected to the first terminal and a third terminal receiving a third voltage, the second output circuit being configured to output a carry signal to a next stage;
a control circuit configured to control voltages of nodes to which the first output circuit and the second output circuit are connected according to a voltage of the first node; and
a selection circuit connected between the control circuit and the first output circuit, and configured to control output of the output signal of the first output circuit,
wherein the second output circuit comprises:
a second pull-up transistor connected to the first terminal and a second output terminal, and comprising a gate connected to a third node;
a second pull-down transistor connected to the second output terminal and the third terminal, and comprising a gate connected to a second node; and
a capacitor connected to the second output terminal and the second node.

19. The electronic device of claim 18, wherein the selection circuit comprises:
a first selection transistor connected to the second node and a fourth node, and comprising a gate connected to a control terminal receiving a selection control signal; and
a second selection transistor connected to the third node and a fifth node, and comprising a gate connected to the control terminal.

20. A display device comprising:
a display panel including a display area divided into a plurality of regions;
a controller configured to generate a driving control signal based on a received control input; and
a gate driving circuit comprising a plurality of stages, each of the plurality of stages configured to receive the driving control signal and to output a gate signal to a corresponding region of the display area,
wherein each of the plurality of stages comprises:
an input circuit configured to transmit a start signal to a first node;
a first output circuit connected to a first voltage terminal and a second voltage terminal, and configured to output an output signal to a signal line;
a second output circuit connected to the first voltage terminal and a third voltage terminal, and configured to output a carry signal to a subsequent stage;
a control circuit configured to control voltages of one or more nodes associated with the first output circuit and the second output circuit based on a voltage of the first node; and
a selection circuit configured to control whether the output signal is output from the first output circuit, based on the driving control signal,
wherein the output signal and the carry signal are generated using different voltage swing range.
